(19) United States
(12) Patent Application Publication
(10) Pub. No.: US 2025/0380565 A1
(43) Pub. Date: Dec. 11, 2025

(54) DISPLAY APPARATUS

(71) Applicant: Samsung Display Co., Ltd., Yongin-si (KR)

(72) Inventors: Jinouk Song, Yongin-si (KR); Ilhoo Park, Yongin-si (KR); Jinsook Bang, Yongin-si (KR); Sanghoon Yim, Yongin-si (KR); Seongjin Jeong, Yongin-si (KR)

(21) Appl. No.: 19/030,654

(22) Filed: Jan. 17, 2025

(30) Foreign Application Priority Data
Jun. 10, 2024 (KR) 10-2024-0075287

(51) Int. Cl. H10K 50/12; H10K 59/122; H10K 59/80; H10K 85/30; H10K 85/60

(52) U.S. Cl. CPC H10K 50/12; H10K 59/122; H10K 59/80515; H10K 85/342; H10K 85/346; H10K 85/348; H10K 85/615; H10K 85/636; H10K 85/654; H10K 85/656; H10K 85/6572; H10K 85/658

(57) ABSTRACT

A display apparatus is disclosed. The display apparatus may include a substrate including a first substrate surface, an organic insulating (e.g., electrically insulating) layer on the first substrate surface, a third pixel electrode on the organic insulating (e.g., electrically insulating) layer, a third emission layer on the third pixel electrode, and a pixel defining layer to define a third opening that is to expose a central portion of the third pixel electrode. The third emission layer may include a dopant material including a phosphorescent dopant, a thermally activated delayed fluorescent dopant, or any combination thereof. The third pixel electrode may include a third-1 electrode area that is to overlap the third opening and may include a sloped area and a flattened area and a third-2 electrode area that is to overlap the pixel defining layer.

### CROSS-REFERENCE TO RELATED APPLICATION

The present application claims priority to and the benefit of Korean Patent Application No. 10-2024-0075287, filed on Jun. 10, 2024, in the Korean Intellectual Property Office, the entire disclosure of which is incorporated herein by reference.

### BACKGROUND

### 1. Field

One or more embodiments of the present disclosure relate to a display apparatus, and, for example, to a display apparatus having an excellent or suitable color gamut.

### 2. Description of the Related Art

As the demand for display apparatuses expands, it is desirable to develop display apparatuses for one or more suitable purposes. Due to such a trend, display apparatuses tend to be manufactured larger or thinner. Therefore, it is desirable to develop larger and thinner display apparatuses that provide accurate and vivid colors.

Display apparatuses include display elements capable of emitting red light, green light, or blue light and may provide images by using these display elements. To this end, each of the display elements includes an emission layer. To improve or enhance the light emission efficiency and/or the like, the emission layer of the display element capable of emitting blue light may include a phosphorescent dopant or a thermally activated delayed fluorescent dopant.

### SUMMARY

However, such display apparatuses that are generally available do not cover a portion of a color gamut required or desired to be covered, and thus, the display quality of these display apparatuses may deteriorate.

One or more aspects of embodiments of the present disclosure are directed toward a display apparatus having an excellent or suitable color gamut. In one or more embodiments, the display quality of the display apparatus may be improved or enhanced. However, this is merely an example, and the scope of the present disclosure is not limited thereby.

Additional aspects of embodiments will be set forth in part in the description which follows and, in part, will be apparent from the description, or may be learned by practice of the presented embodiments of the disclosure.

According to one or more embodiments, a display apparatus includes a substrate including a first substrate surface and a second substrate surface opposite to the first substrate surface, an organic insulating (e.g., electrically insulating) layer on the first substrate surface, a first pixel electrode, a second pixel electrode, and a third pixel electrode apart (e.g., arranged apart) from each other on the organic insulating (e.g., electrically insulating) layer, a first emission layer on the first pixel electrode, wherein the first emission layer is to emit red light, a second emission layer on the second pixel electrode, wherein the second emission layer is to emit green light, a third emission layer on the third pixel electrode, wherein the third emission layer is to emit blue light, and a pixel defining layer to define a first opening to expose a central portion of the first pixel electrode, a second opening to expose a central portion of the second pixel electrode, and a third opening to expose a central portion of the third pixel electrode, wherein the third emission layer includes a dopant material including a phosphorescent dopant, a thermally activated delayed fluorescent dopant, or any combination thereof, a wavelength indicated by a peak having a maximum intensity in a photoluminescence (PL) spectrum of light emitted by the dopant material is about 460 nm to about 490 nm, and the third pixel electrode includes a third-1 electrode area and a third-2 electrode area, the third-1 electrode area is to overlap the third opening and includes a sloped area and a flattened area, and the third-2 electrode area is to overlap the pixel defining layer.

The third pixel electrode may include a third-1 electrode surface in a direction opposite to the substrate and a third-2 electrode surface in a direction of the substrate, the third-1 electrode surface of the sloped area may be inclined with respect to the first substrate surface, and the third-1 electrode surface of the flattened area may be parallel (e.g., substantially parallel) to the first substrate surface.

An angle between the third-1 electrode surface of the sloped area and the first substrate surface may be about 10° to about 80°.

In a plan view, the sloped area may surround the flattened area.

The sloped area may be adjacent to an inner surface of the pixel defining layer that is to define the third opening.

The first pixel electrode may include a first-1 electrode surface in a direction opposite to the substrate and a first-2 electrode surface in a direction of the substrate, the second pixel electrode may include a second-1 electrode surface in a direction opposite to the substrate and a second-2 electrode surface in a direction of the substrate, the first-1 electrode surface of the first pixel electrode may be parallel (e.g., substantially parallel) to the first substrate surface, and the second-1 electrode surface of the second pixel electrode may be parallel (e.g., substantially parallel) to the first substrate surface.

The display apparatus may further include an opposite electrode across the first pixel electrode, the second pixel electrode, and the third pixel electrode.

The phosphorescent dopant may include an organometallic compound represented by Formula 401:

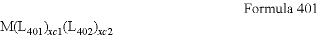

wherein, in Formula 401, M may be a transition metal,
L₄₀₁ may be a ligand represented by Formula 402, xc1 may be 1, 2, or 3, and if (e.g., when) xc1 is 2 or 3, two or more L₄₀₁(s) may be identical to or different from each other, and
L₄₀₂ may be an organic ligand, xc2 may be 0, 1, 2, 3, or 4, and if (e.g., when) xc2 is 2, 3, or 4, two or more L₄₀₂(s) may be identical to or different from each other,

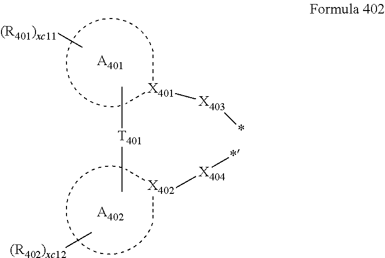

wherein, in Formula 402,
X₄₀₁ and X₄₀₂ may each independently be nitrogen (N) or carbon (C),
a ring A₄₀₁ and a ring A₄₀₂ may each independently be a C₈-C₆₀ carbocyclic group or a C₁-C₆₀ heterocyclic group,
T₄₀₁ may be a single bond (e.g., a single covalent bond), *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)═*′, or *═C═*′,
X₄₀₃ and X₄₀₄ may each independently be a chemical bond (e.g., a covalent bond), O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₅-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
xc11 and xc12 may each independently be an integer of 0 to 10,
* and *′ may each indicate a binding site to M in Formula 401, and
R₁₀ₐ may be selected from among:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —Ge(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —Ge(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —Ge(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁₁ to Q₁₃, Q₂₁ to Q₂₃, Q₃₁ to Q₃₃, Q₄₀₁ to Q₄₀₃, and Q₄₁₁ to Q₄₁₄ may each independently be hydrogen; deuterium; —F; —Cl; —Br; —I; a hydroxyl group; a cyano group; a nitro group; a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, a cyano group, a phenyl group, a biphenyl group, or any combination thereof; or a C₃-C₆₀ carbocyclic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or any combination thereof.

A difference between a triplet energy level (eV) of the thermally activated delayed fluorescent dopant and a singlet energy level (eV) of the thermally activated delayed fluorescent dopant may be about 0 eV to about 0.5 eV.

The thermally activated delayed fluorescent dopant may include a material including at least one electron donor and at least one electron acceptor, a material including a C₈-C₆₀ polycyclic group including two or more cyclic groups condensed (e.g., coupled covalently) while sharing a boron atom (B), or any combination thereof.

According to one or more embodiments, a display apparatus includes a substrate including a first substrate surface and a second substrate surface opposite to the first substrate surface, an organic insulating (e.g., electrically insulating) layer on the first substrate surface, a first pixel electrode, a second pixel electrode, and a third pixel electrode apart (e.g., arranged apart) from each other on the organic insulating (e.g., electrically insulating) layer, a first emission layer on the first pixel electrode, wherein the first emission layer is to emit red light, a second emission layer on the second pixel electrode, wherein the second emission layer is to emit green light, a third emission layer on the third pixel electrode, wherein the third emission layer is to emit blue light, and a pixel defining layer to define a first opening to expose a central portion of the first pixel electrode, a second opening to expose a central portion of the second pixel electrode, and a third opening to expose a central portion of the third pixel electrode, wherein the third emission layer includes a dopant material including a phosphorescent dopant, a thermally activated delayed fluorescent dopant, or any combination thereof, a wavelength indicated by a peak having a maximum intensity in a photoluminescence (PL) spectrum of light emitted by the dopant material is about 460 nm to about 490 nm, and the third pixel electrode includes a third-1 electrode area and a third-2 electrode area, the third-1 electrode area is to overlap the third opening and includes a flattened area and a convex area, and the third-2 electrode area is to overlap the pixel defining layer.

The third pixel electrode may include a third-1 electrode surface in a direction opposite to the substrate and a third-2 electrode surface in a direction of the substrate, the third-1 electrode surface of at least a portion of the convex area may be inclined with respect to the first substrate surface, and the third-1 electrode surface of the flattened area may be parallel (e.g., substantially parallel) to the first substrate surface.

An angle between the third-1 electrode surface of the convex area adjacent to the flattened area and the first substrate surface may be about 10° to about 80°.

In a plan view, the flattened area may surround the convex area.

The flattened area may be adjacent to an inner surface of the pixel defining layer that is to define the third opening.

The first pixel electrode may include a first-1 electrode surface in a direction opposite to the substrate and a first-2 electrode surface in a direction of the substrate, the second pixel electrode may include a second-1 electrode surface in a direction opposite to the substrate and a second-2 electrode surface in a direction of the substrate, the first-1 electrode surface of the first pixel electrode may be parallel (e.g., substantially parallel) to the first substrate surface, and the second-1 electrode surface of the second pixel electrode may be parallel (e.g., substantially parallel) to the first substrate surface.

The display apparatus may further include an opposite electrode across the first pixel electrode, the second pixel electrode, and the third pixel electrode.

The phosphorescent dopant may include an organometallic compound represented by Formula 401:

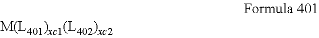

wherein, in Formula 401, M may be a transition metal,
L₄₀₁ may be a ligand represented by Formula 402, xc1 may be 1, 2, or 3, and if (e.g., when) xc1 is 2 or 3, two or more L₄₀₁(s) may be identical to or different from each other, and
L₄₀₂ may be an organic ligand, xc2 may be 0, 1, 2, 3, or 4, and if (e.g., when) xc2 is 2, 3, or 4, two or more L₄₀₂(s) may be identical to or different from each other,

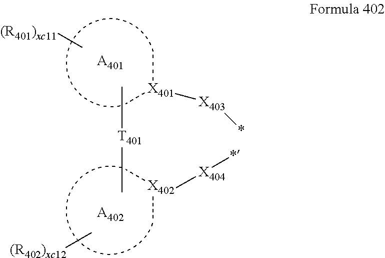

wherein, in Formula 402,
X₄₀₁ and X₄₀₂ may each independently be nitrogen (N) or carbon (C),
a ring A₄₀₁ and a ring A₄₀₂ may each independently be a C₃-C₆₀ carbocyclic group or a C₁-C₆₀ heterocyclic group,
T₄₀₁ may be a single bond (e.g., a single covalent bond), *—O—*′, *—S—*′, *—C(═O)—*′, *—N(Q₄₁₁)-*′, *—C(Q₄₁₁)(Q₄₁₂)-*′, *—C(Q₄₁₁) ═C(Q₄₁₂)-*′, *—C(Q₄₁₁)═*′, or *═C═*′,
X₄₀₃ and X₄₀₄ may each independently be a chemical bond (e.g., a covalent bond), O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂), xc11 and xc12 may each independently be an integer of 0 to 10,
* and *′ may each indicate a binding site to M in Formula 401, and
R₁₀ₐ may be selected from among:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —Ge(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₅-C₆₀ carbocyclic group, a C₁-C₆₀ heterocyclic group, a C₆-C₆₀ aryloxy group, or a C₆-C₆₀ arylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —Ge(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —Ge(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁₁ to Q₁₃, Q₂₁ to Q₂₃, Q₃₁ to Q₃₃, Q₄₀₁ to Q₄₀₃, and Q₄₁₁ to Q₄₁₄ may each independently be hydrogen; deuterium; —F; —Cl; —Br; —I; a hydroxyl group; a cyano group; a nitro group; a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, a cyano group, a phenyl group, a biphenyl group, or any combination thereof; or a C₃-C₆₀ carbocyclic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or any combination thereof.

A difference between a triplet energy level (eV) of the thermally activated delayed fluorescent dopant and a singlet energy level (eV) of the thermally activated delayed fluorescent dopant may be about 0 eV to about 0.5 eV.

The thermally activated delayed fluorescent dopant may include a material including at least one electron donor and at least one electron acceptor, a material including a C₈-C₆₀ polycyclic group including two or more cyclic groups condensed (e.g., coupled covalently) while sharing a boron atom (B), or any combination thereof.

Other aspects, effects, and/or embodiments of the present disclosure will become better understood through the detailed description, the appended claims and equivalents thereof, and the accompanying drawings.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a plan view schematically illustrating a portion of a display apparatus according to one or more embodiments;

FIG. 2 is an equivalent circuit diagram of a pixel circuit included in a display apparatus according to one or more embodiments;

FIG. 3 is an enlarged view of a region A of the display apparatus of FIG. 1;

FIG. 4 is a cross-sectional view taken along line I-I′ of FIG. 3 and schematically illustrating the display apparatus of FIG. 3;

FIG. 5 is an enlarged view of a region B of FIG. 4;

FIG. 6 is an enlarged view of a region C of FIG. 4;

FIG. 7 is an enlarged view of a region D of FIG. 4;

FIG. 8 is a plan view schematically illustrating a portion of a display apparatus according to one or more embodiments;

FIG. 9 is a graph illustrating color coordinates of Comparative Examples 1-2;

FIG. 10 is an enlarged view of a region E of FIG. 9;

FIG. 11 is a cross-sectional view schematically illustrating a portion of a display apparatus according to one or more embodiments;

FIG. 12 is a plan view schematically illustrating a portion of a display apparatus according to one or more embodiments;

FIG. 13 is a cross-sectional view schematically illustrating a portion of a display apparatus according to one or more embodiments;

FIG. 14 is a cross-sectional view schematically illustrating a portion of a display apparatus according to one or more embodiments;

FIG. 15 is a plan view schematically illustrating a portion of a display apparatus according to one or more embodiments;

FIG. 16 is a conceptual diagram schematically illustrating a portion of a display apparatus according to one or more embodiments; and

FIG. 17 is a cross-sectional view schematically illustrating a display apparatus according to one or more embodiments.

### DETAILED DESCRIPTION

Reference will be made in more detail to one or more embodiments, examples of which are illustrated in the accompanying drawings, wherein like reference numerals refer to like elements throughout. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

As used herein, the term “and/or” includes any and all combinations of one or more of the associated listed items. Throughout the present disclosure, the expression “at least one of a, b, or c” (or “at least one selected from among a, b, or c”) indicates only a, only b, only c, both a and b, both a and c, both b and c, all of a, b, and c, or variations thereof.

As the present description allows for one or more suitable changes and embodiments, certain embodiments will be illustrated in the accompanying drawings and described in more detail in the written description. The aspects, effects, and/or embodiments of the present disclosure and methods of achieving them will be clarified with reference to one or more embodiments and the accompanying drawings described below in more detail. However, the disclosure is not limited to the disclosed embodiments and may be embodied in one or more suitable forms.

In one or more embodiments, the terms such as “first,” “second,” and/or the like are not used in a restrictive sense but are used to distinguish one element from another.

The singular forms “a,” “an,” and “the” as used herein are intended to include the plural forms as well unless the context clearly indicates otherwise.

In one or more embodiments, it should be understood that the terms “include” and/or “have” as used herein specify the presence of stated features, integers, steps, operations, constituent elements, components and/or a combination thereof, but do not preclude the presence or addition of one or more other features, integers, steps, operations, constituent elements, components and/or a combination thereof.

In one or more embodiments, the expression “A and/or B” indicates only A, only B, or both A and B. In one or more embodiments, the expression “at least one of A and B” (or “at least one selected from among A and B”) indicates only A, only B, or both A and B.

In one or more embodiments, it will be understood that, if (e.g., when) an element, such as a layer, a film, a region, a plate, and/or the like, is referred to as being “on” another element, the element may be “directly on” the other element, and intervening elements may be present therebetween. In contrast, if (e.g., when) an element is referred to as being “directly on” another element, there are no intervening elements present.

It will be further understood that if (e.g., when) layers, regions, elements, and/or the like, are referred to as being connected to each other, they may be directly connected to each other or indirectly connected to each other with intervening layers, regions, elements, and/or the like therebetween. For example, if (e.g., when) layers, regions, elements, and/or the like are referred to as being electrically connected to each other, they may be directly electrically connected to each other or indirectly electrically connected to each other with intervening layers, regions, elements, and/or the like therebetween. In contrast, if (e.g., when) layers, regions, elements, and/or the like are referred to as being “directly” electrically connected to each other, there are no intervening layers, regions, elements, and/or the like present.

In one or more embodiments, the x-axis, the y-axis, and the z-axis are not limited to three axes of the rectangular coordinate system and may be interpreted in a broader sense. For example, the x-axis, the y-axis, and the z-axis may be perpendicular (e.g., substantially perpendicular) to one another or may represent different directions that are not perpendicular (e.g., not substantially perpendicular) to one another.

The term “in a plan view” as used herein refers to seeing a target portion from above. For example, in one or more embodiments, the term “in a plan view” as used herein may refer to “if (e.g., when) viewed from a direction perpendicular (e.g., substantially perpendicular) to a substrate.”

Hereinafter, the subject matter of the present disclosure will be described in more detail with reference to the accompanying drawings. If (e.g., when) describing one or more embodiments with reference to the accompanying drawings, substantially the same or corresponding elements are denoted by the same reference numerals, and redundant descriptions thereof may not be provided. For convenience of illustration, sizes of elements in the drawings may be exaggerated or reduced. For example, because sizes and thicknesses of elements in the drawings are arbitrarily illustrated for convenience of description, embodiments of the present disclosure are not limited thereto.

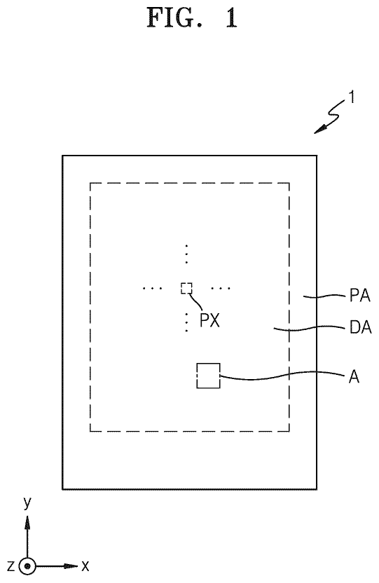

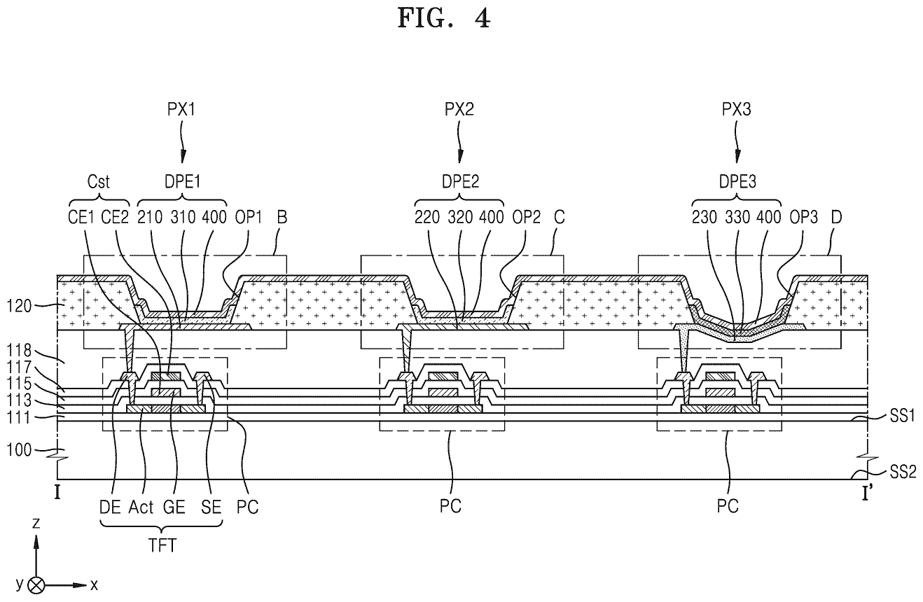

FIG. 1 is a plan view schematically illustrating a portion of a display apparatus 1 according to one or more embodiments. As illustrated in FIG. 1, the display apparatus 1 may include a display area DA in which a plurality of pixels PX are provided and a peripheral area PA outside the display area DA. For example, the peripheral area PA may completely (e.g., substantially completely) surround the display area DA. It may be understood that a substrate (see 100 of FIG. 4) included in the display apparatus 1 includes the display area DA and the peripheral area PA.

The plurality of pixels PX of the display apparatus 1 may be areas in which pieces of light of certain colors are emitted, and the display apparatus 1 may provide images by using the pieces of light emitted from the plurality of pixels PX. The plurality of pixels PX may externally emit, for example, red light, green light, or blue light.

The display area DA may have a polygonal shape, such as a rectangular (e.g., substantially rectangular) shape, as illustrated in FIG. 1. For example, the display area DA may have a rectangular (e.g., substantially rectangular) shape in which a horizontal length is longer than a vertical length, a rectangular (e.g., substantially rectangular) shape in which a horizontal length is shorter than a vertical length, or a square (e.g., substantially square) shape. In one or more embodiments, the display area DA may have other shapes, such as an elliptical (e.g., substantially elliptical) shape or a circular (e.g., substantially circular) shape.

The peripheral area PA may be a non-display area in which the plurality of pixels PX are not provided. A driver and/or the like to provide electrical signals or power to the plurality of pixels PX may be in the peripheral area PA. Pads, to which one or more suitable electronic devices or a printed circuit board may be electrically connected, may be in the peripheral area PA. The pads may be apart (e.g., arranged apart) from each other in the peripheral area PA and may be electrically connected to a printed circuit board or integrated circuit devices.

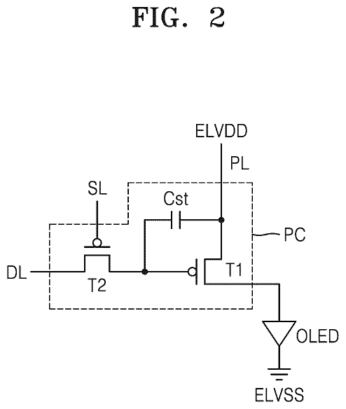

FIG. 2 is an equivalent circuit diagram of a pixel circuit PC included in the display apparatus 1 of FIG. 1 according to one or more embodiments. The pixel circuit PC may be electrically connected to a display element. One display element may correspond to one pixel PX. In FIG. 2, an organic light-emitting diode OLED is illustrated as the display element.

The pixel circuit PC may include a first transistor T1, a second transistor T2, and a storage capacitor Cst. The second transistor T2, which acts as a switching transistor, may be connected (e.g., electrically connected) to a scan line SL and a data line DL and may be to be turned on in response to a switching signal input from the scan line SL and transmit, to the first transistor T1, a data signal input from the data line DL. The storage capacitor Cst may have one end electrically connected to the second transistor T2 and the other end electrically connected to a driving voltage line PL and may store a voltage corresponding to a difference between a voltage received from the second transistor T2 and a driving power supply voltage ELVDD supplied to the driving voltage line PL.

The first transistor T1, which acts as a driving transistor, may be connected (e.g., electrically connected) to the driving voltage line PL and the storage capacitor Cst and may be to control an amount of a driving current flowing from the driving voltage line PL to the organic light-emitting diode OLED according to a voltage value stored in the storage capacitor Cst. The organic light-emitting diode OLED may be to emit light with a certain luminance according to the driving current. An opposite electrode of the organic light-emitting diode OLED may be to receive an electrode power supply voltage ELVSS.

Although FIG. 2 illustrates that the pixel circuit PC includes two transistors and one storage capacitor, embodiments of the present disclosure are not limited thereto. For example, the number of transistors or the number of storage capacitors may be suitably changed according to the design of the pixel circuit PC.

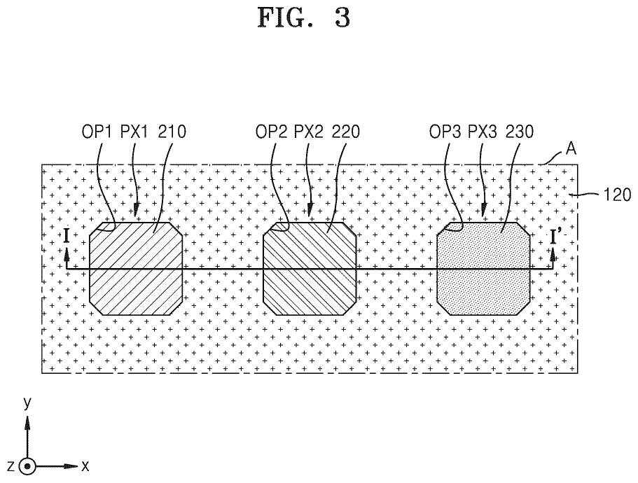

FIG. 3 is an enlarged view of a region A of the display apparatus 1 of FIG. 1. FIG. 3 is a plan view on a pixel defining layer 120. As illustrated in FIG. 3, a plurality of pixels PX may be in a display area DA. Each of the plurality of pixels PX refers to a sub-pixel, and one display element, such as an organic light-emitting diode, may correspond to one pixel PX. The plurality of pixels PX may be to externally emit, for example, red light, green light, or blue light. For example, the pixel PX may be a first pixel PX1 to emit red light, a second pixel PX2 to emit green light, or a third pixel PX3 to emit blue light. The red light may be light in a wavelength band of about 580 nm to about 780 nm, the green light may be light in a wavelength band of about 495 nm to about 580 nm, and the blue light may be light in a wavelength band of about 400 nm to about 495 nm.

For example, each of the display elements included in the display apparatus 1 corresponds to each of the plurality of pixels PX of the display apparatus 1, and each of the display elements may be to emit red light, green light, or blue light. For example, the display element corresponding to the first pixel PX1 may be to emit red light, the display element corresponding to the second pixel PX2 may be to emit green light, and the display element corresponding to the third pixel PX3 may be to emit blue light. In one or more embodiments, the expression “one display element corresponds to one pixel, or one pixel corresponds to one display element” refers to that one pixel is the emission area of one display element.

For example, a first pixel electrode 210, a second pixel electrode 220, and a third pixel electrode 230 may be in the display area DA of the substrate (see 100 of FIG. 4). The pixel defining layer 120 may be on the first pixel electrode 210, the second pixel electrode 220, and the third pixel electrode 230. The pixel defining layer 120 may be to define a first opening OP1, a second opening OP2, and a third opening OP3. The first opening OP1 may be to expose the central portion of the first pixel electrode 210, the second opening OP2 may be to expose the central portion of the second pixel electrode 220, and the third opening OP3 may be to expose the central portion of the third pixel electrode 230. Although not illustrated in FIG. 3, emission layers to emit light may be respectively within the first opening OP1, the second opening OP2, and the third opening OP3 of the pixel defining layer 120. The opposite electrode may be on the emission layers.

The stacked structure of the pixel electrode, the emission layer, and the opposite electrode may form or provide one display element, such as an organic light-emitting diode. One opening of the pixel defining layer 120 may be to define the emission area of one display element. For example, the emission layer to emit red light may be within the first opening OP1, and the emission area defined by the first opening OP1 may be defined as the first pixel PX1. In one or more embodiments, the emission layer to emit green light may be within the second opening OP2, and the emission area defined by the second opening OP2 may be defined as the second pixel PX2. In one or more embodiments, the emission layer to emit blue light may be within the third opening OP3, and the emission area defined by the third opening OP3 may be defined as the third pixel PX3.

In one or more embodiments, in a plan view, the first pixel electrode 210, the second pixel electrode 220, and the third pixel electrode 230 may be apart (e.g., arranged apart) from each other. For example, the first pixel electrode 210 and the second pixel electrode 220 may be adjacent to each other in the first direction (e.g., the x-axis direction), and the third pixel electrode 230 may be in a direction opposite to a direction of the first pixel electrode 210 with the second pixel electrode 220 therebetween. In one or more embodiments, the first opening OP1 and the second opening OP2 may be adjacent to the first direction (e.g., the x-axis direction), and the third opening OP3 may be in a direction opposite to a direction of the first opening OP1 with the second opening OP2 therebetween.

Although FIG. 3 illustrates that the first opening OP1, the second opening OP2, and the third opening OP3 have substantially the same size, embodiments of the present disclosure are not limited thereto. The first opening OP1, the second opening OP2, and the third opening OP3 may have substantially different sizes. In one or more embodiments, the first pixel electrode 210, the second pixel electrode 220, and the third pixel electrode 230 may have substantially the same size, or the first pixel electrode 210, the second pixel electrode 220, and the third pixel electrode 230 may have substantially different sizes.

FIG. 4 is a cross-sectional view taken along line I-I′ of FIG. 3 and schematically illustrating the display apparatus 1 of FIG. 3. As illustrated in FIG. 4, the display apparatus 1 according to one or more embodiments may include a substrate 100.

The substrate 100 may include one or more suitable flexible (e.g., substantially flexible) or bendable (e.g., substantially bendable) materials. For example, the substrate 100 may include glass, metal, and/or a polymer resin. In one or more embodiments, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, cellulose acetate propionate, and/or a combination thereof. In one or more embodiments, one or more suitable modifications may be made. For example, the substrate 100 may have a multilayer structure that includes two layers and a barrier layer therebetween, wherein the two layers may include a polymer resin and the barrier layer may include an inorganic material (e.g., silicon oxide (e.g., SiO_{X}, wherein 0<X≤2), silicon nitride (e.g., Si₃N₄), and/or silicon oxynitride (e.g., Si₂N₂O or SiO_{X}N_{Y}, wherein 0<X≤2 and 0≤Y≤2)).

The substrate 100 may include a first substrate surface SS1 and a second substrate surface SS2 that is the opposite surface of the first substrate surface SS1. For example, the first substrate surface SS1 may be the upper surface of the substrate 100 (in the +z direction), and the second substrate surface SS2 may be the lower surface of the substrate 100 (in the −z direction).

A display element and a pixel circuit PC electrically connected to the display element may be on the first substrate surface SS1 of the substrate 100. For example, a first display element DPE1, a second display element DPE2, and a third display element DPE3 may be on the substrate 100. The first display element DPE1 may correspond to the first pixel PX1, the second display element DPE2 may correspond to the second pixel PX2, and the third display element DPE3 may correspond to the third pixel PX3. For example, the display element may be an organic light-emitting diode.

For example, a plurality of pixel circuits PC may be on the substrate 100. Each of the pixel circuits PC may be electrically connected to the first display element DPE1, the second display element DPE2, or the third display element DPE3. Because the structures of the pixel circuits PC electrically connected to the first display element DPE1, the second display element DPE2, or the third display element DPE3 are substantially identical to each other, the following description is given to focus on one pixel circuit PC. The pixel circuit PC may include a plurality of transistors TFT and a storage capacitor Cst. For convenience of description, one transistor TFT is illustrated in FIG. 4, and the transistor TFT may correspond to the first transistor (see T₁ of FIG. 2) as described in one or more embodiments.

A buffer layer 111 may be between the transistor TFT and the substrate 100. The buffer layer 111 may include an inorganic material, such as silicon oxide (e.g., SiO_{X}, wherein 0<X≤2), silicon nitride (e.g., Si₃N₄), and/or silicon oxynitride (e.g., Si₂N₂₀ or SiO_{X}N_{Y}, wherein 0<X≤2 and 0≤Y≤2). The buffer layer 111 may increase or enhance the smoothness of the first substrate surface SS1 of the substrate 100 or may prevent (or minimize or reduce) infiltration of impurities (e.g., may reduce a degree or occurrence of infiltration of undesirable impurities) from the substrate 100 and/or the like to a semiconductor layer Act of the transistor TFT.

As illustrated in FIG. 4, the transistor TFT may include the semiconductor layer Act including amorphous silicon, polycrystalline silicon, an organic semiconductor material, and/or an oxide semiconductor material. The transistor TFT may include a gate electrode GE, a source electrode SE, and/or a drain electrode DE. The gate electrode GE may include one or more suitable conductive (e.g., electrically conductive) materials and have one or more suitable layered structures. For example, the gate electrode GE may include a molybdenum (Mo) layer and an aluminum (Al) layer. In one or more embodiments, the gate electrode GE may include a titanium nitride (e.g., TiN_{X}, wherein 0<X≤2) layer, an Al layer, and/or a Ti layer. The source electrode SE and the drain electrode DE may also include one or more suitable conductive (e.g., electrically conductive) materials and have one or more suitable layered structures, For example, each of the source electrode SE and the drain electrode DE may include a Ti layer, an Al layer, and/or a copper (Cu) layer.

In order to ensure or provide electrical insulation between the semiconductor layer Act and the gate electrode GE, a gate insulating layer 113 may be between the semiconductor layer Act and the gate electrode GE. The gate insulating layer 113 may include an inorganic material, such as silicon oxide (e.g., SiO_{X}, wherein 0<X≤2), silicon nitride (e.g., Si₃N₄), and/or silicon oxynitride (e.g., Si₂N₂O or SiO_{X}N_{Y}, wherein 0<X≤2 and 0≤Y≤2). Although FIG. 4 illustrates that the gate insulating layer 113 has a shape corresponding to the entire (e.g., substantially entire) surface of the substrate 100 and has a structure in which contact holes are formed in preset portions, embodiments of the present disclosure are not limited thereto. For example, the gate insulating layer 113 may be patterned to have substantially the same shape as the gate electrode GE.

In one or more embodiments, a first interlayer insulating layer 115 may be on the gate electrode GE. The first interlayer insulating layer 115 may include an inorganic insulating (e.g., electrically insulating) material, such as silicon oxide (e.g., SiO_{X}, wherein 0<X≤2), silicon nitride (e.g., Si₃N₄), and/or silicon oxynitride (e.g., Si₂N₂O or SiO_{X}N_{Y}, wherein 0<X≤2 and 0≤Y≤2). The first interlayer insulating layer 115 may have a single-layer or multilayer structure including the material as described in one or more embodiments. The first interlayer insulating layer 115 including the inorganic material as described in one or more embodiments may be provided by depositions (e.g., chemical vapor deposition (CVD) and/or atomic layer deposition (ALD)). Substantially the same applies to one or more embodiments and modifications to be further described below.

The storage capacitor Cst may include a first capacitor electrode CE1 and a second capacitor electrode CE2 that overlap each other with the first interlayer insulating layer 115 therebetween. The storage capacitor Cst may overlap the transistor TFT. For example, FIG. 4 illustrates that the gate electrode GE of the transistor TFT is the first capacitor electrode CE1 of the storage capacitor Cst, but embodiments of the present disclosure are not limited thereto. For example, the storage capacitor Cst may not overlap the transistor TFT. The second capacitor electrode CE2 of the storage capacitor Cst may include a conductive (e.g., electrically conductive) material including molybdenum (Mo), aluminum (AI), copper (Cu), and/or titanium (Ti) and may include a single layer or two or more layers including the conductive (e.g., electrically conductive) material as described in one or more embodiments.

A second interlayer insulating layer 117 may be on the second capacitor electrode CE2 of the storage capacitor Cst. The second interlayer insulating layer 117 may include an inorganic material, such as silicon oxide (e.g., SiO_{X}, wherein 0<X≤2), silicon nitride (e.g., Si₃N₄), and/or silicon oxynitride (e.g., Si₂N₂O or SiO_{X}N_{Y}, wherein 0<X≤2 and 0≤Y≤2). The second interlayer insulating layer 117 may have a single-layer or multilayer structure including the inorganic material as described in one or more embodiments.

The source electrode SE and the drain electrode DE may be on the second interlayer insulating layer 117. Each of the source electrode SE and the drain electrode DE may include a material having excellent or suitable conductivity (e.g., electrical conductivity). Each of the source electrode SE and the drain electrode DE may include a conductive (e.g., electrically conductive) material including molybdenum (Mo), aluminum (AI), copper (Cu), and/or titanium (Ti) and may include a single-layer or multilayer structure including the conductive (e.g., electrically conductive) material as described in one or more embodiments. For example, each of the source electrode SE and the drain electrode DE may have a multilayer structure of Ti/Al/Ti.

However, embodiments of the present disclosure are not limited thereto. For example, the transistor TFT may include only one of the source electrode SE and the drain electrode DE or may not include both (e.g., simultaneously) of the source electrode SE and the drain electrode DE. For example, one transistor TFT may not include the drain electrode DE, another transistor TFT connected (e.g., electrically connected) to the transistor TFT may not include the source electrode SE, and the semiconductor layers Act of the two transistors may be connected (e.g., electrically connected) to each other. Such a connection (e.g., electrical connection) structure may have substantially the same effect as a case where one transistor TFT also includes the source electrode SE, another transistor TFT also includes the drain electrode DE, and the source electrode SE of the one transistor TFT is connected (e.g., electrically connected) to the drain electrode DE of the other transistor TFT.

As illustrated in FIG. 4, an organic insulating layer 118 may be to cover the transistor TFT and the storage capacitor Cst. For example, the organic insulating layer 118 may be on the first substrate surface SS1 of the substrate 100. The organic insulating layer 118 may include an organic insulating (e.g., electrically insulating) material. For example, the organic insulating layer 118 may include a photoresist, benzocyclobutene (BCB), polyimide, hexamethyldisiloxane (HMDSO), poly(methyl methacrylate) (PMMA), polystyrene, polymer derivatives having a phenolic group, an acrylic polymer, an imide-based polymer, an aryl ether-based polymer, an amide-based polymer, a fluorine-based polymer, a p-xylene-based polymer, a vinyl alcohol-based polymer, or any mixture thereof. Although not illustrated in FIG. 4, a third interlayer insulating layer may be further below the organic insulating layer 118. The third interlayer insulating layer may include an inorganic insulating (e.g., electrically insulating) material, such as silicon oxide (e.g., SiO_{X}, wherein 0<X≤2), silicon nitride (e.g., Si₃N₄), and/or silicon oxynitride (e.g., Si₂N₂O or SiO_{X}N_{Y}, wherein 0<X≤2 and 0≤Y≤2).

The first display element DPE1, the second display element DPE2, and the third display element DPE3 may be apart (e.g., arranged apart) from each other on the organic insulating layer 118. For example, the first display element DPE1 and the second display element DPE2 may be adjacent to each other on the organic insulating layer 118 in the first direction (e.g., the x-axis direction), and the third display element DPE3 may be adjacent to the second display element DPE2 on the organic insulating layer 118 in the first direction (e.g., the x-axis direction). For example, the third display element DPE3 may be on the organic insulating layer 118 in a direction opposite to a direction of the first display element DPE1 with the second display element DPE2 therebetween.

The first display element DPE1, the second display element DPE2, and the third display element DPE3 may emit light of substantially different colors. For example, the first display element DPE1 may be to emit red light, the second display element DPE2 may be to emit green light, and the third display element DPE3 may be to emit blue light. The first display element DPE1 may include a first pixel electrode 210, a first emission layer 310, and an opposite electrode 400. The second display element DPE2 may include a second pixel electrode 220, a second emission layer 320, and an opposite electrode 400, and the third display element DPE3 may include a third pixel electrode 230, a third emission layer 330, and an opposite electrode 400. The opposite electrode 400 may be integrally provided across the entire (e.g., substantially entire) surface of the display apparatus 1, and thus, may be provided to be generally available for a plurality of display elements.

The first pixel electrode 210, the second pixel electrode 220, and the third pixel electrode 230 may be apart (e.g., arranged apart) from each other and may be on the organic insulating layer 118. For example, the second pixel electrode 220 may be adjacent to the first pixel electrode 210 on the organic insulating layer 118 in the first direction (e.g., the x-axis direction). The third pixel electrode 230 may be adjacent to the second pixel electrode 220 on the organic insulating layer 118 in the first direction (e.g., the x-axis direction). For example, the third pixel electrode 230 may be on the organic insulating layer 118 in a direction opposite to a direction of the first pixel electrode 210 with the second pixel electrode 220 therebetween. Each of the first pixel electrode 210, the second pixel electrode 220, and the third pixel electrode 230 may include a transmissive conductive (e.g., electrically conductive) layer and a reflective layer. The transmissive conductive (e.g., electrically conductive) layer may include a transmissive conductive (e.g., electrically conductive) oxide, such as indium tin oxide (ITO), indium oxide (e.g., In₂O₃), and/or indium zinc oxide (IZO), and the reflective layer may include metal, such as aluminum (Al) and/or silver (Ag). For example, each of the first pixel electrode 210, the second pixel electrode 220, and the third pixel electrode 230 may have a three-layer structure of ITO/Ag/ITO.

The first pixel electrode 210, the second pixel electrode 220, and the third pixel electrode 230 may be in contact with one of the source electrode SE and the drain electrode DE, and thus, may be electrically connected to the transistor TFT, as illustrated in FIG. 4. For example, each of the first pixel electrode 210, the second pixel electrode 220, and the third pixel electrode 230 may be in contact with one of the source electrode SE and the drain electrode DE through a contact hole in the organic insulating layer 118.

A pixel defining layer 120 may be on the organic insulating layer 118. As described in one or more embodiments, the pixel defining layer 120 may be to define a first opening OP1, a second opening OP2, and a third opening OP3. The first opening OP1 may be to expose the central portion of the first pixel electrode 210 of the first display element DPE1, the second opening OP2 may be to expose the central portion of the second pixel electrode 220 of the second display element DPE2, and the third opening OP3 may be to expose the central portion of the third pixel electrode 230 of the third display element DPE3. For example, because the pixel defining layer 120 has an inner surface that defines an opening corresponding to a pixel, for example, an opening that exposes at least the central portion of the pixel electrode, the pixel defining layer 120 may define a pixel.

In one or more embodiments, as illustrated in FIG. 4, the pixel defining layer 120 may increase the distance between the edges of the first pixel electrode 210, the second pixel electrode 220, and the third pixel electrode 230 and the opposite electrode 400 on the first pixel electrode 210, the second pixel electrode 220, and the third pixel electrode 230. For this reason, an electric arc and/or the like may be prevented or reduced from occurring at the edges of the first pixel electrode 210, the edge of the second pixel electrode 220, and/or the edge of the third pixel electrode 230. The pixel defining layer 120 may include, for example, an organic material, such as polyimide or HMDSO.

The opposite electrode 400 may be on the first pixel electrode 210. The opposite electrode 400 may be integrally provided across the first display element DPE1, the second display element DPE2, and/or the third display element DPE3. Therefore, the opposite electrode 400 may also be on the second pixel electrode 220 and/or the third pixel electrode 230. For example, the opposite electrode 400 may be across the first pixel electrode 210, the second pixel electrode 220, and/or the third pixel electrode 230. The opposite electrode 400 may include a transmissive conductive (e.g., electrically conductive) layer including ITO, indium oxide (e.g., In₂O₃), and/or IZO, and may also include a semi-transmissive layer including metal, such as Al and/or Ag. For example, the opposite electrode 400 may be a semi-transmissive layer including magnesium (Mg) and/or Ag.

The first emission layer 310 to emit red light may be between the first pixel electrode 210 and the opposite electrode 400. The second emission layer 320 to emit green light may be between the second pixel electrode 220 and the opposite electrode 400, and the third emission layer 330 to emit blue light may be between the third pixel electrode 230 and the opposite electrode 400. For example, the first emission layer 310 to emit red light may be on the first pixel electrode 210. The second emission layer 320 to emit green light may be on the second pixel electrode 220, and the third emission layer 330 to emit blue light may be on the third pixel electrode 230.

Each of the first emission layer 310, the second emission layer 320, and the third emission layer 330 may include, for example, an organic material. For example, the first emission layer 310, the second emission layer 320, and the third emission layer 330 may include an organic material capable of emitting light of a certain color (e.g., red, green, or blue).

For example, the first emission layer 310 may include an organic material capable of emitting red light, and the second emission layer 320 may include an organic material capable of emitting green light. For example, each of the first emission layer 310 and the second emission layer 320 may include a polymer material, such as polyphenylenevinylene (PPV) and/or polyfluorene. However, embodiments of the present disclosure are not limited thereto.

In one or more embodiments, the third emission layer 330 may include a first dopant material, and the first dopant material may include a phosphorescent dopant, a thermally activated delayed fluorescent dopant, or any combination thereof.

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

The phosphorescent dopant may include an organometallic compound represented by Formula 401:

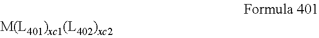

wherein, in Formula 401, M may be a transition metal,
L₄₀₁ may be a ligand represented by Formula 402, xc1 may be 1, 2, or 3, and if (e.g., when) xc1 is 2 or 3, two or more L₄₀₁(s) may be identical to or different from each other, and
L₄₀₂ may be an organic ligand, xc2 may be 0, 1, 2, 3, or 4, and if (e.g., when) xc2 is 2, 3, or 4, two or more L₄₀₂(s) may be identical to or different from each other,

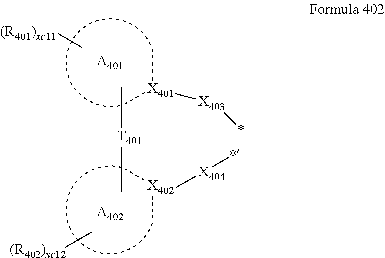

wherein, in Formula 402,
X₄₀₁ and X₄₀₂ may each independently be nitrogen (N) or carbon (C),
a ring A₄₀₁ and a ring A₄₀₂ may each independently be a C₃-C₆₀ carbocyclic group or a C₁-C₆₀ heterocyclic group,
T₄₀₁ may be a single bond (e.g., a single covalent bond), *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)═*′, or *═C═*′,
X₄₀₃ and X₄₀₄ may each independently be a chemical bond (e.g., a covalent bond), O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
xc11 and xc12 may each independently be an integer of 0 to 10,
* and *′ may each indicate a binding site to M in Formula 401, and
R₁₀ₐ may be selected from among:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —Ge(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —Ge(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —Ge(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁₁ to Q₁₃, Q₂₁ to Q₂₃, Q₃₁ to Q₃₃, Q₄₀₁ to Q₄₀₃, and Q₄₁₁ to Q₄₁₄ may each independently be hydrogen; deuterium; —F; —Cl; —Br; —I; a hydroxyl group; a cyano group; a nitro group; a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, a cyano group, a phenyl group, a biphenyl group, or any combination thereof; or a C₃-C₆₀ carbocyclic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or any combination thereof.

For example, in Formula 402, i) X₄₀₁ may be nitrogen and X₄₀₂ may be carbon or ii) both X₄₀₁ and X₄₀₂ may be nitrogen.

For example, if (e.g., when) xc1 in Formula 401 is 2 or 3, two rings A₄₀₁ among two or more L₄₀₁(s) may be optionally connected (e.g., covalently connected) to each other via a linking group T₄₀₂, or two rings A₄₀₂ may be optionally connected (e.g., covalently connected) to each other via a linking group T₄₀₃ (see Compounds PD1 to PD4 and PD7). The description of T₄₀₂ and T₄₀₃ refers to the description of T₄₀₁ in one or more embodiments of the present disclosure.

In Formula 401, L₄₀₂ may be any suitable organic ligand. For example, L₄₀₂ may include a halogen group, a diketone group (e.g., an acetylacetonate group), a carboxylic acid group (e.g., a picolinate group), —C(═O), an isonitrile group, —CN group, a phosphorus group (e.g., a phosphine group, a phosphite group, and/or the like), or any combination thereof.

The phosphorescent dopant may include, for example, one selected from among Compounds PD1 to PD39 or any combination thereof:

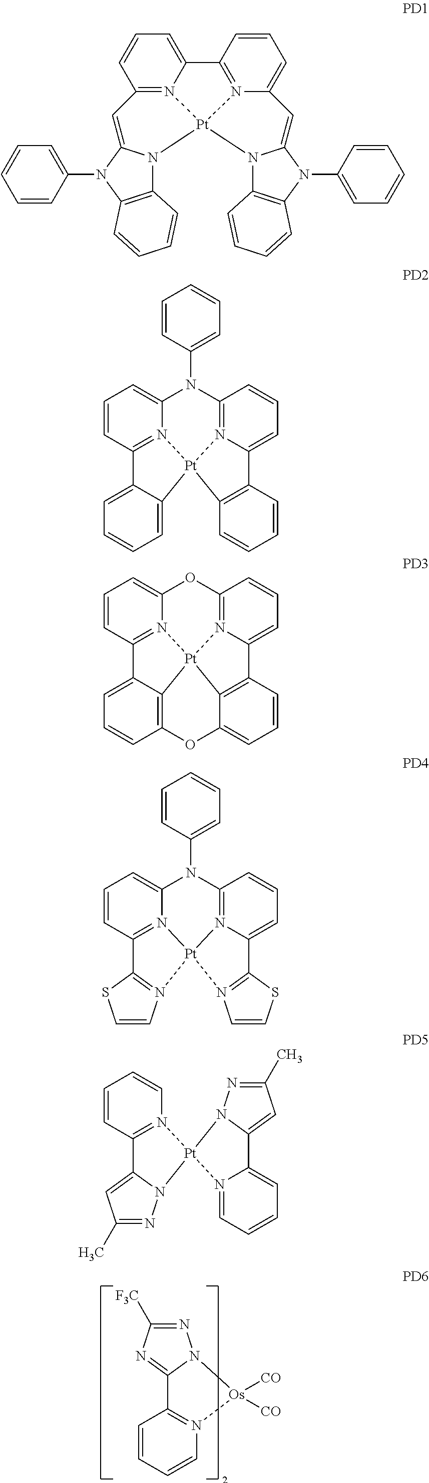

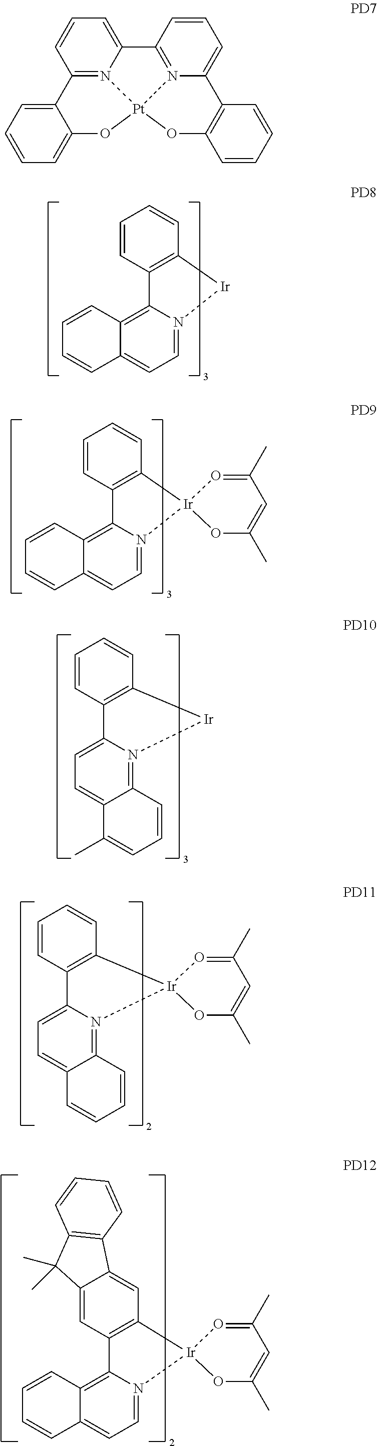

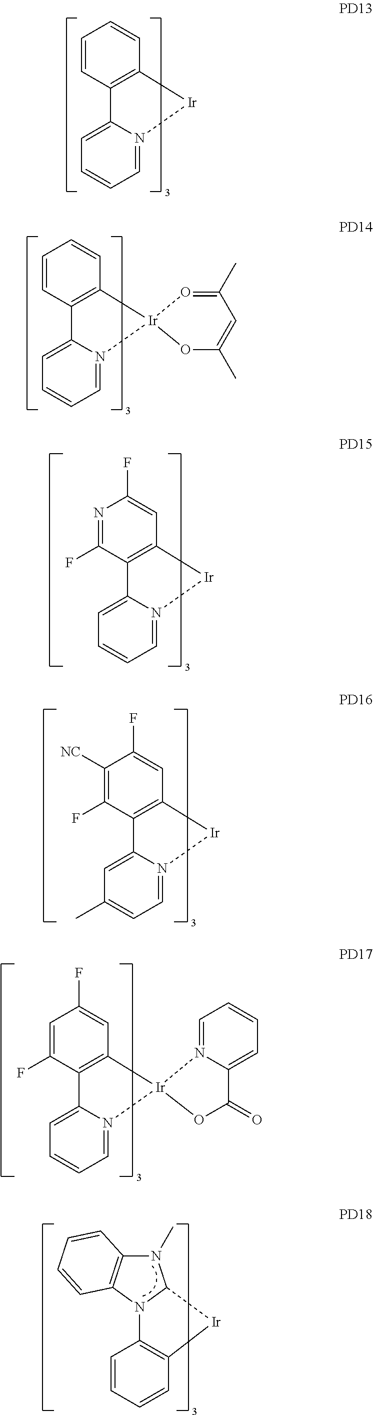

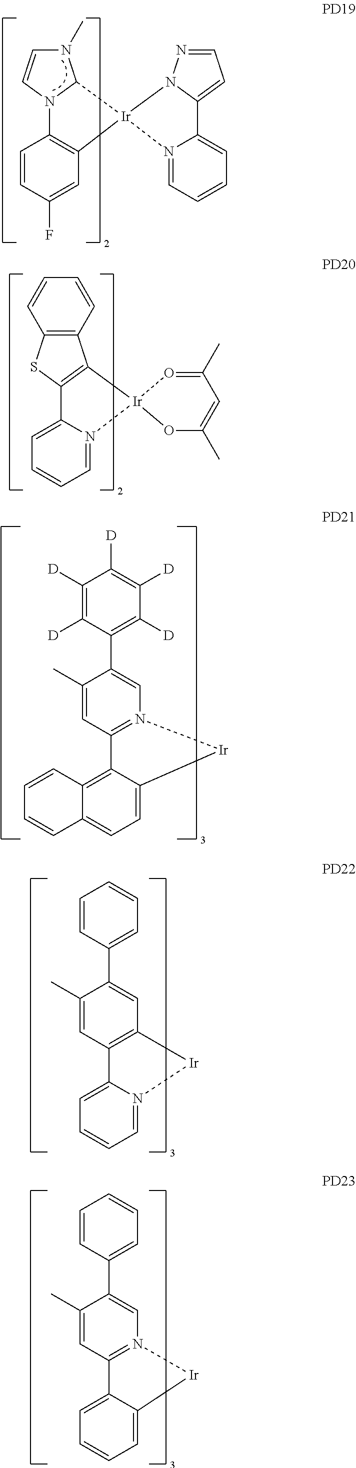

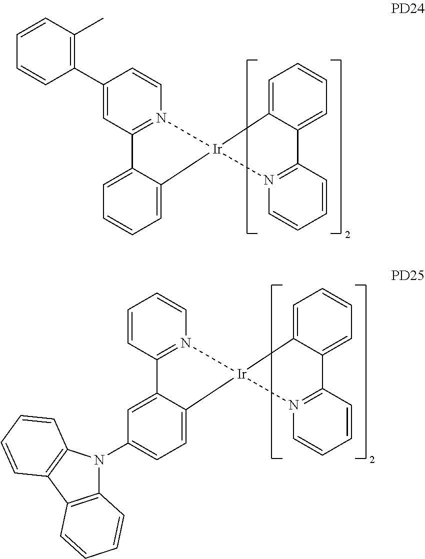

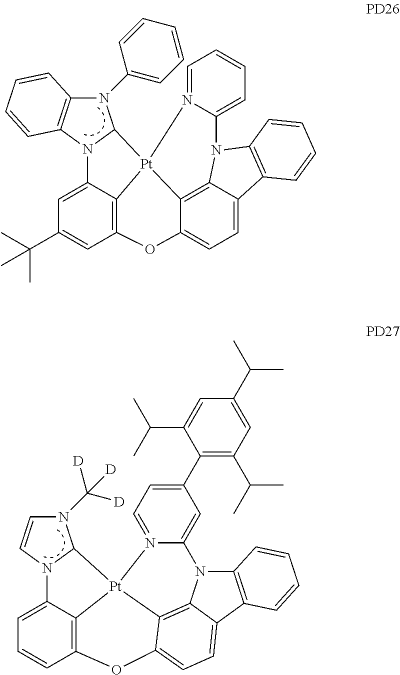

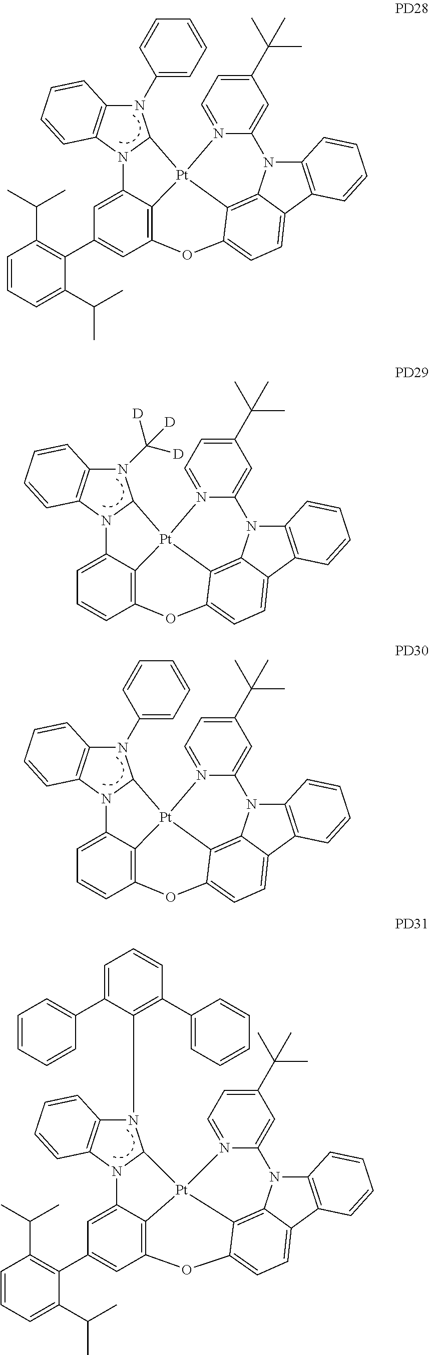

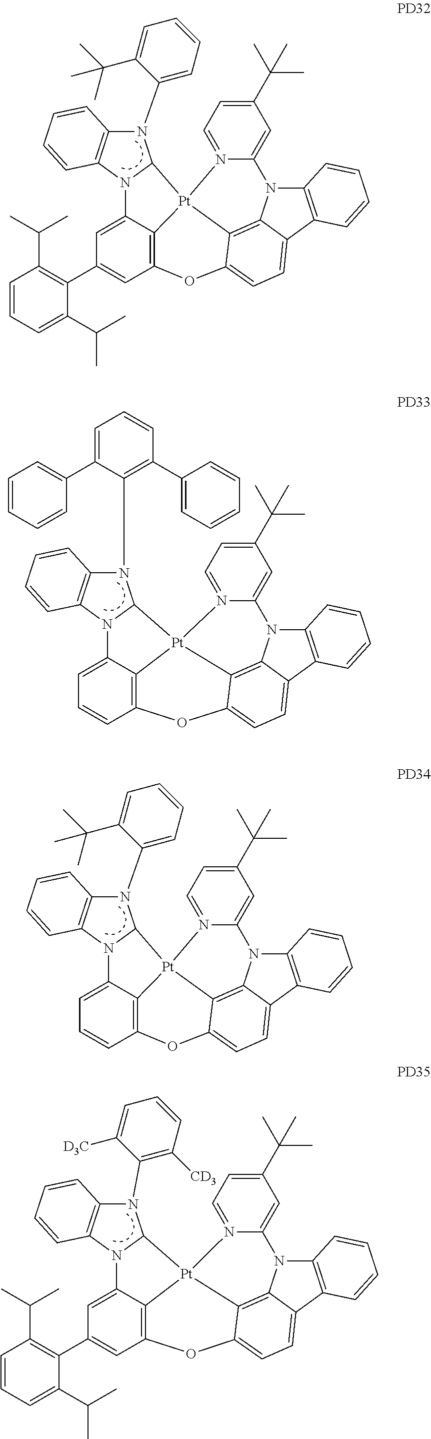

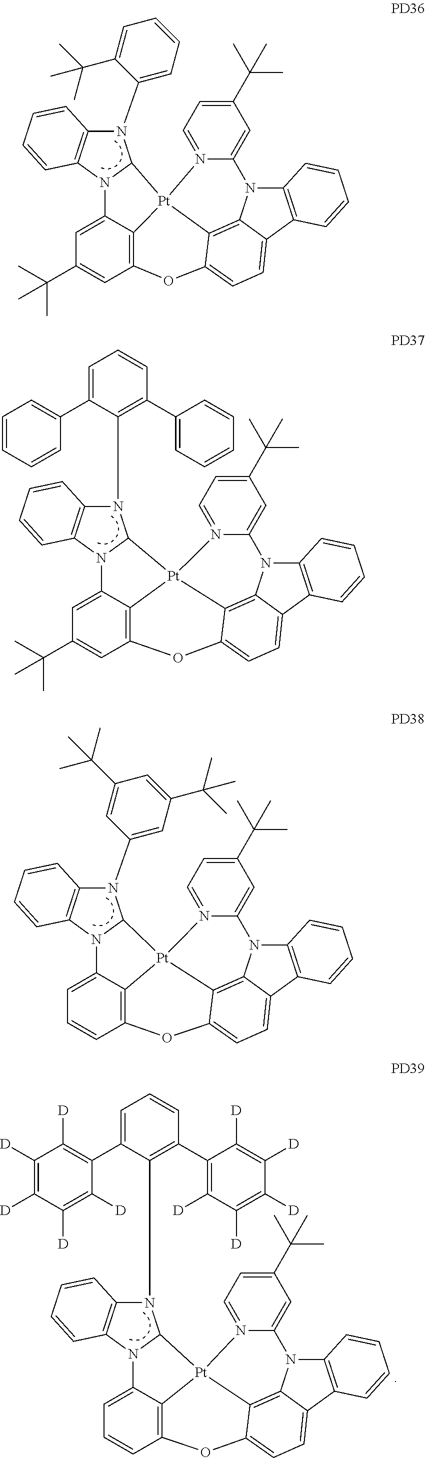

The thermally activated delayed fluorescent dopant may be selected from among any suitable compound capable of emitting delayed fluorescence by a delayed fluorescence emission mechanism.

According to one or more embodiments, the difference between the triplet energy level (eV) of the thermally activated delayed fluorescent dopant and the singlet energy level (eV) of the thermally activated delayed fluorescent dopant may be about 0 eV to about 0.5 eV, about 0 eV to about 0.4 eV, or about 0 eV to 0.3 eV. If (e.g., when) the difference between the triplet energy level (eV) of the thermally activated delayed fluorescent dopant and the singlet energy level (eV) of the thermally activated delayed fluorescent dopant satisfies the foregoing ranges, up-conversion from the triplet state to the singlet state of the thermally activated delayed fluorescent dopant may be effectively or suitably achieved or provided, and thus, the light emission efficiency of the display element and/or the like may be improved or enhanced.

For example, the thermally activated delayed fluorescent dopant may include i) a material including at least one electron donor (e.g., a IT electron-rich C₃-C₆₀ cyclic group, such as a carbazole group and/or the like) and at least one electron acceptor (e.g., a sulfoxide group, a cyano group, a Tr electron-deficient nitrogen-containing C₁-C₆₀ cyclic group, and/or the like), and/or ii) a material including a C₈-C₆₀ polycyclic group including two or more cyclic groups condensed (e.g., coupled covalently) while sharing a boron atom (B) and/or the like.

1 Examples of the thermally activated delayed fluorescent dopant may include at least one selected from among Compounds DF1 to DF14:

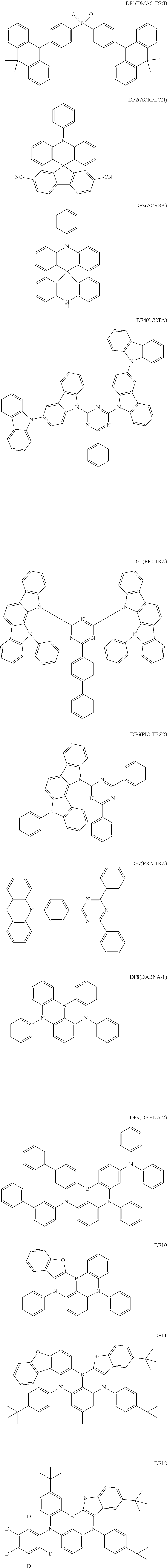

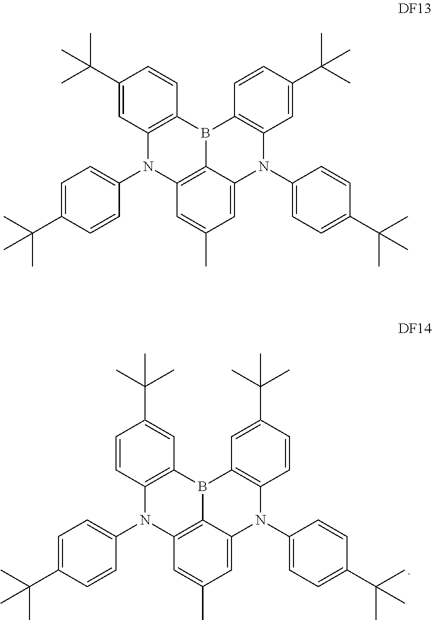

According to one or more embodiments, the third emission layer 330 may further include, in addition to the first dopant material, a first host material. For example, the third emission layer 330 may include the first dopant material and the first host material. In the third emission layer 330, a content (e.g., amount) of the first host material may be greater than a content (e.g., amount) of the first dopant material, based on a weight. For example, the weight of the first dopant material may be 5 parts by weight or more based on 100 parts by weight of the third emission layer 330 or may be 15 parts by weight or less based on 100 parts by weight of the third emission layer 330.

The first host material may be a material having a triplet energy level higher than a triplet energy level of a dopant included in the first dopant material.

For example, the first host material may be selected from: the group consisting of aromatic hydrocarbon cyclic compounds, such as benzene, biphenyl, triphenyl, triphenylene, naphthalene, anthracene, phenalene, phenanthrene, fluorene, pyrene, chrysene, perylene, azulene, and/or the like; the group consisting of aromatic heterocyclic compounds, such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthen, acridine, phenazine, phenothiazine, phenoxazine, benzofuropyridine, furodipyridine, benzothienopyridine, thienodipyridine, benzoselenophenopyridine, selenophenodipyridine, and/or the like; and/or the group consisting of 2 to 10 ring structural units which are of substantially the same or different types or kinds selected from among the aromatic hydrocarbon ring group and the aromatic heterocyclic group and which are bonded to each other directly or through at least one selected from among an oxygen atom, a nitrogen atom, a sulfur atom, a silicon atom, a phosphorus atom, a boron atom, a chain structural unit, and an alicyclic group. Each group may be further substituted by a substituent selected from the group consisting of hydrogen, alkyl, alkoxy, amino, alkenyl, alkynyl, arylalkyl, heteroalkyl, aryl, and heteroaryl.

The first host material may include at least one selected from among the following groups within a molecule:

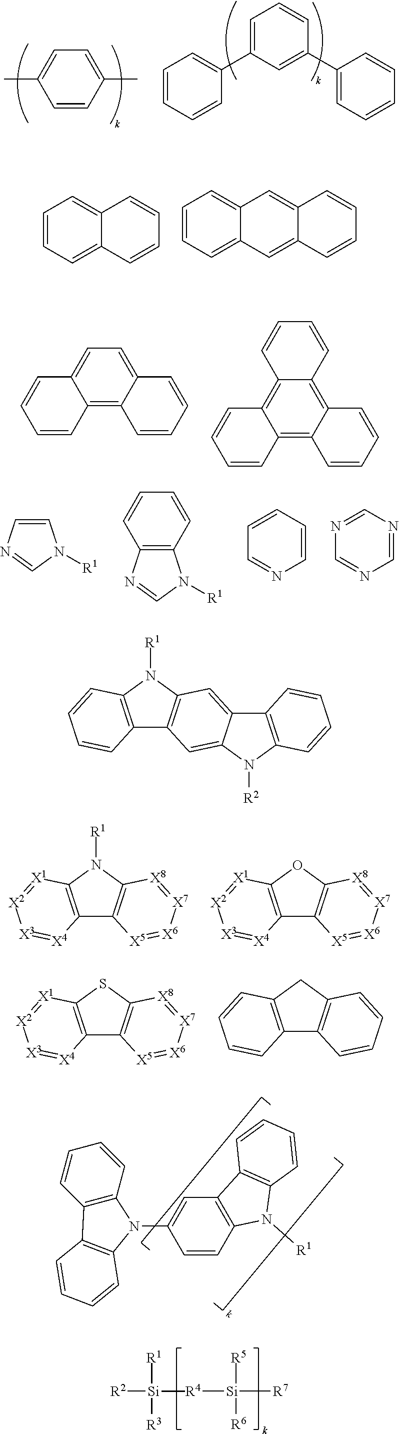

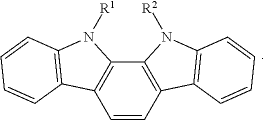

R₁ to R₇ may each independently be selected from the group consisting of hydrogen, alkyl, alkoxy, amino, alkenyl, alkynyl, arylalkyl, heteroalkyl, aryl, and heteroaryl. If (e.g., when) R₁ to R₇ are aryl or heteroaryl, the aryl or the heteroaryl may be selected from: the group consisting of aromatic hydrocarbon cyclic compounds, such as benzene, biphenyl, triphenyl, triphenylene, naphthalene, anthracene, phenalene, phenanthrene, fluorene, pyrene, chrysene, perylene, azulene, and/or the like; the group consisting of aromatic heterocyclic compounds, such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthenes, acridines, phenazines, phenothiazines, phenoxazines, benzofuropyridines, furodipyridines, benzothienopyridines, thienodipyridines, benzoselenophenopyridine, selenophenodipyridine, and/or the like; and/or the group consisting of 2 to 10 ring structural units which are of substantially the same or different types or kinds selected from among the aromatic hydrocarbon ring group and the aromatic heterocyclic group and which are bonded to each other directly or through at least one selected from among an oxygen atom, a nitrogen atom, a sulfur atom, a silicon atom, a phosphorus atom, a boron atom, a chain structural unit, and an alicyclic group.

k may be an integer of 0 to 20.

X¹ to X⁸ may be selected from CH or N.

According to one or more embodiments, the first dopant material included in the third emission layer 330 may emit first light, and a wavelength indicated by a peak having a maximum intensity in a photoluminescence (PL) spectrum of the first light may be about 460 nm to about 490 nm. For example, a wavelength indicated by a peak having a maximum intensity in a PL spectrum of light emitted by the dopant material included in the third emission layer 330 may be about 460 nm to about 490 nm. The wavelength (or maximum emission wavelength) indicated by the peak having the maximum intensity of the first light, as described in one or more embodiments, may be evaluated from the PL spectrum for the film including the first dopant material. For example, the wavelength may be evaluated from the PL spectrum of light emitted if (e.g., when) excitation light is irradiated onto the film including the first dopant material and the first host material. If (e.g., when) the film is irradiated with the excitation light, the PL spectrum of the emitted light may be mainly or predominantly affected by the first dopant material, and the effect of the first host material may be minimal or reduced. For example, because the first dopant material is a major factor affecting the PL spectrum of the light emitted if (e.g., when) the film is irradiated with the excitation light, the PL spectrum of the light emitted, if (e.g., when) the film is irradiated with the excitation light, may vary depending on the first dopant material, regardless of the material included in the first host material.

For example, after mixing 4,4′,4-tris(carbazol-9-yl)triphenylamine (TCTA) and the first dopant material (6 wt % relative to TCTA) in a CH₂Cl₂ solution, the resultant obtained therefrom may be coated on a quartz substrate by using a spin coater and may be then heat-treated in an oven at 80° C. and cooled to room temperature to thereby manufacture a 40 nm-thick evaluation film. The PL spectrum of the evaluation film may be measured by using an analyzer, for example, a Hamamatsu Quantaurus-QY Absolute PL quantum yield spectrometer (mounted with a xenon light source, a monochromator, a photonic multichannel analyzer, and an integrating sphere and employing PLQY measurement software (Hamamatsu Photonics, Ltd., Shizuoka, Japan)). The wavelength indicated by the peak having the maximum intensity of the first light by using the measured PL spectrum may be evaluated.

In one or more embodiments, the phosphorescent dopant may emit light in the excited state of the triplet state, and the energy level of the triplet state of the phosphorescent dopant may be about 2.53 eV to about 2.70 eV. In one or more embodiments, the wavelength indicated by the peak having the maximum intensity of light emitted in the excited state of the triplet state of the phosphorescent dopant may be about 460 nm to about 490 nm. The thermally activated delayed fluorescent dopant may emit light in the excited state of the singlet state, and the energy level of the singlet state of the thermally activated delayed fluorescent dopant may be about 2.53 eV to about 2.70 eV. In one or more embodiments, the wavelength indicated by the peak having the maximum intensity of light emitted in the excited state of the singlet state of the thermally activated delayed fluorescent dopant may be about 460 nm to about 490 nm.

For example, the first dopant material including the phosphorescent dopant, the thermally activated delayed fluorescent dopant, or any combination thereof may emit the first light, and the wavelength indicated by the peak having the maximum intensity of the first light may be about 460 nm to about 490 nm. In one or more embodiments, if (e.g., when) a film includes a plurality of dopants, energy transfer may occur between the dopants, and this energy transfer may result in the emission of light corresponding to the energy with the smallest energy difference between the ground state and the excited state.

In one or more embodiments, functional layers may be below and above the first emission layer 310, the second emission layer 320, and the third emission layer 330. The functional layers may include a hole injection layer (HIL), a hole transport layer (HTL), an electron transport layer (ETL), and/or an electron injection layer (EIL). The functional layers may be integrally formed or provided across the first pixel electrode 210, the second pixel electrode 220, and/or the third pixel electrode 230 or may be patterned to correspond to the first pixel electrode 210, the second pixel electrode 220, and the third pixel electrode 230, respectively.

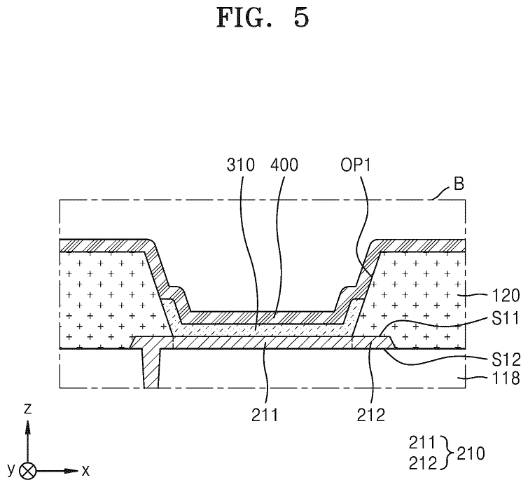

FIG. 5 is an enlarged view of a region B of FIG. 4. As illustrated in FIG. 5, the first pixel electrode 210 may include a first-1 electrode area 211 and a first-2 electrode area 212. The first-1 electrode area 211 may overlap the first opening OP1, and the first-2 electrode area 212 may overlap the pixel defining layer 120. For example, the pixel defining layer 120 may not be between the first-1 electrode area 211 and the first emission layer 310 on the first-1 electrode area 211, but the pixel defining layer 120 may be between the first-2 electrode area 212 and the first emission layer 310 on the first-2 electrode area 212. The first-2 electrode area 212 may be integrally provided with the first-1 electrode area 211.

In one or more embodiments, the first pixel electrode 210 may include a first-1 electrode surface S11 and a first-2 electrode surface S12. The first-1 electrode surface S11 may be a surface in the direction opposite to the substrate 100, and the first-2 electrode surface S12 may be a surface in the direction of the substrate 100. For example, the first-1 electrode surface S11 may be the upper surface of the first pixel electrode 210 (in the +z direction) and the first-2 electrode surface S12 may be the lower surface of the first pixel electrode 210 (in the −z direction). The first-1 electrode surface S11 of the first pixel electrode 210 may be parallel (e.g., substantially parallel) to the first substrate surface SS1 of the substrate 100. For example, the first pixel electrode 210 may not include an area inclined with respect to the first substrate surface SS1 of the substrate 100.

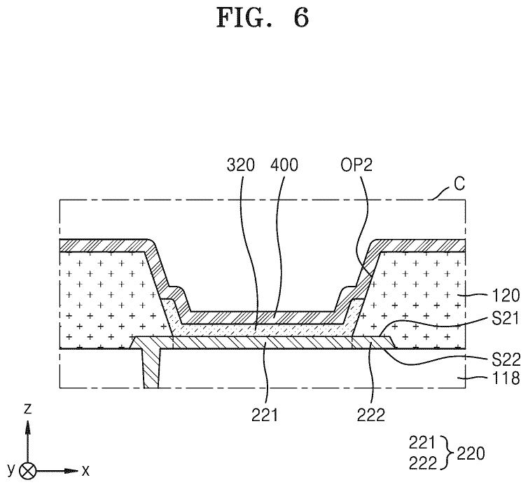

FIG. 6 is an enlarged view of a region C of FIG. 4. As illustrated in FIG. 6, the second pixel electrode 220 may include a second-1 electrode area 221 and a second-2 electrode area 222. The second-1 electrode area 221 may overlap the second opening OP2, and the second-2 electrode area 222 may overlap the pixel defining layer 120. For example, the pixel defining layer 120 may not be between the second-1 electrode area 221 and the second emission layer 320 on the second-1 electrode area 221, but the pixel defining layer 120 may be between the second-2 electrode area 222 and the second emission layer 320 on the second-2 electrode area 222. The second-2 electrode area 222 may be integrally provided with the second-1 electrode area 221.

In one or more embodiments, the second pixel electrode 220 may include a second-1 electrode surface S21 and a second-2 electrode surface S22. The second-1 electrode surface S21 may be a surface in the direction opposite to the substrate 100, and the second-2 electrode surface S22 may be a surface in the direction of the substrate 100. For example, the second-1 electrode surface S21 may be the upper surface of the second pixel electrode 220 (in the +z direction) and the second-2 electrode surface S22 may be the lower surface of the second pixel electrode 220 (in the −z direction). The second-1 electrode surface S21 of the second pixel electrode 220 may be parallel (e.g., substantially parallel) to the first substrate surface SS1 of the substrate 100. For example, the second pixel electrode 220 may not include an area inclined with respect to the first substrate surface SS1 of the substrate 100.

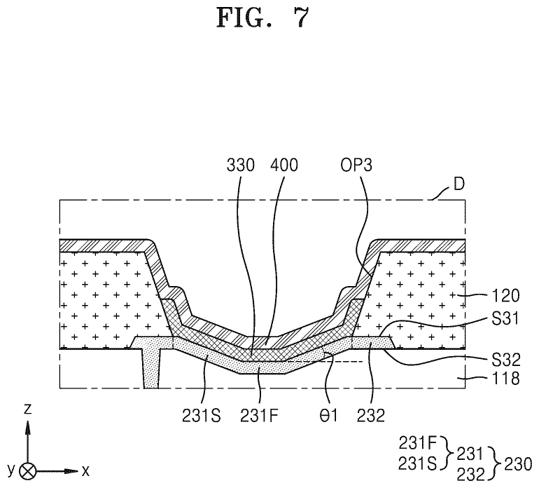

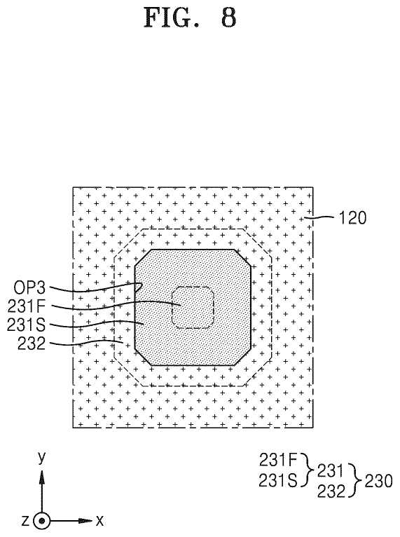

FIG. 7 is an enlarged view of a region D of FIG. 4. FIG. 8 is a plan view schematically illustrating a portion of the display apparatus 1 according to one or more embodiments. FIG. 8 is a plan view on the pixel defining layer 120. However, for convenience of description, a third-2 electrode area 232 below the layer 120 is illustrated together.

As illustrated in FIG. 7, the third pixel electrode 230 may include a third-1 electrode area 231 and the third-2 electrode area 232. The third-1 electrode area 231 may overlap the third opening OP3, and the third-2 electrode area 232 may overlap the pixel defining layer 120. For example, the pixel defining layer 120 may not be between the third-1 electrode area 231 and the third emission layer 330 on the third-1 electrode area 231, but the pixel defining layer 120 may be between the third-2 electrode area 232 and the third emission layer 330 on the third-2 electrode area 232. The third-2 electrode area 232 may be integrally provided with the third-1 electrode area 231.

In one or more embodiments, the third pixel electrode 230 may include a third-1 electrode surface S31 and a third-2 electrode surface S32. The third-1 electrode surface S31 may be a surface in the direction opposite to the substrate 100, and the third-2 electrode surface S32 may be a surface in the direction of the substrate 100. For example, the third-1 electrode surface S31 may be the upper surface of the third pixel electrode 230 (in the +z direction) and the third-2 electrode surface S32 may be the lower surface of the third pixel electrode 230 (in the −z direction). The third-1 electrode area 231 may include a flattened area 231F (e.g., an area having a flat surface or substantially flat surface). The flattened area 231F may be an area where the third-1 electrode surface S31 of the flattened area 231F is parallel (e.g., substantially parallel) to the first substrate surface SS1 of the substrate 100. For example, the third-1 electrode surface S31 of the flattened area 231F may be parallel (e.g., substantially parallel) to the first substrate surface SS1 of the substrate 100.

The third-1 electrode area 231 may further include, in addition to the flattened area 231F, an area inclined with respect to the first substrate surface SS1 of the substrate 100. For example, the third-1 electrode area 231 may further include an area where a normal thereof crosses a direction perpendicular (e.g., substantially perpendicular) to the substrate 100.

In one or more embodiments, the third-1 electrode area 231 may further include a sloped area 231S (e.g., an area having an inclined surface). The sloped area 231S may be an area where the third-1 electrode surface S31 of the sloped area 231S is inclined with respect to the first substrate surface SS1 of the substrate 100. For example, the third-1 electrode surface S31 of the sloped area 231S may be inclined with respect to the first substrate surface SS1 of the substrate 100. For example, an angle between the third-1 electrode surface S31 of the sloped area 231S and the first substrate surface SS1 of the substrate 100 may be a first angle θ1, and the first angle θ1 may be about 10° to about 80°. For example, the distance between the third-1 electrode surface S31 of the sloped area 231S and the first substrate surface SS1 may be greater than the distance between the third-1 electrode surface S31 of the flattened area 231F and the first substrate surface SS1. In one or more embodiments, an angle between one surface of one electrode and the first substrate surface SS1 of the substrate 100 refers to an angle between one surface of one electrode and a plane that is horizontal to the first substrate surface SS1 of the substrate 100.

As illustrated in FIG. 8, the sloped area 231S may surround the flattened area 231F. For example, the flattened area 231F may be surrounded by the sloped area 231S, and the sloped area 231S may be surrounded by the third-2 electrode area 232. For example, in a plan view, the sloped area 231S may surround the flattened area 231F. In one or more embodiments, the sloped area 231S may be adjacent to the inner surface of the pixel defining layer 120 that is to define the third opening OP3. However, embodiments of the present disclosure are not limited thereto.

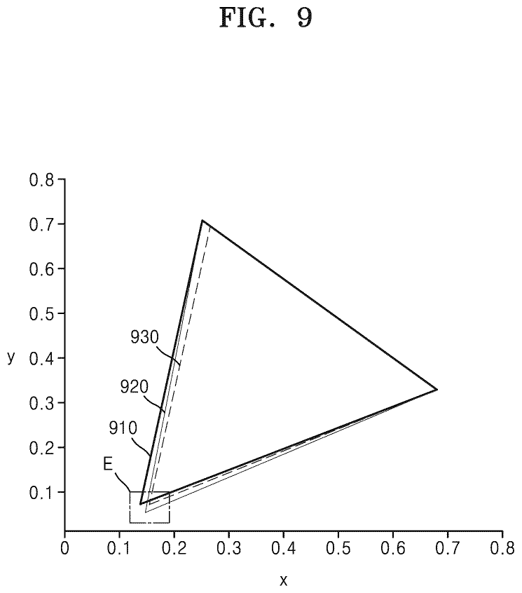

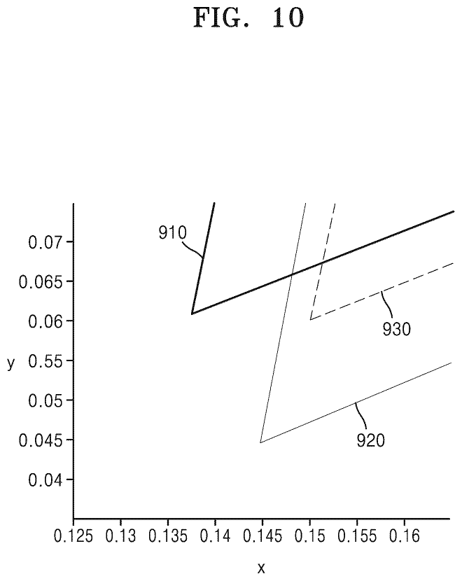

FIG. 9 is a graph illustrating color coordinates of Comparative Examples 1-2. FIG. 10 is an enlarged view of a region E of FIG. 9. In FIGS. 9 and 10, color coordinates 910 of Comparative Example 1 and color coordinates 920 of Comparative Example 2 are illustrated in comparison with the standard color coordinates (hereinafter referred to as DCI-P3) 930 based on the CIE 1931 color coordinate system. In FIGS. 9 and 10, the horizontal axis represents the x-coordinate value in the CIE 1931 color coordinate system, and the vertical axis represents the y-coordinate value in the CIE 1931 color coordinate system. For example, the color coordinates of Comparative Examples 1-2 were calculated by using a PL spectrum and a MATLAB-based CIE color coordinate calculator. By using this, the color gamuts of Comparative Examples 1-2 were represented in a triangular (e.g., substantially triangular) shape.

The third-1 electrode area 231 of Comparative Example 1 and the third-1 electrode area 231 of Comparative Example 2 include only the flattened area 231F and do not include an area inclined with respect to the first substrate surface SS1 of the substrate 100. However, the third emission layer 330 of Comparative Example 1 includes a phosphorescent dopant, a thermally activated delayed fluorescent dopant, or any combination thereof as a dopant material. The third emission layer 330 of Comparative Example 2 includes a generally used or generally available fluorescent dopant as a dopant material. In one or more embodiments, the DCI-P3 color gamut may be a color gamut defined by the Digital Cinema Initiatives for use as a color gamut of a digital projector in the American film industry.

In one or more embodiments, as a wavelength indicated by a peak having a maximum intensity in a PL spectral region of a luminous body that emits blue light is greater, a y-coordinate value in a CIE 1931 color coordinate system may increase. For example, as illustrated in FIGS. 9 and 10, Comparative Example 1, in which the third emission layer 330 includes a phosphorescent dopant, a thermally activated delayed fluorescent dopant, or any combination thereof as a dopant material, has a greater y-coordinate value in the CIE 1931 color coordinate system than Comparative Example 2, in which the third emission layer 330 includes a generally used or generally available fluorescent dopant as a dopant material. In one or more embodiments, as illustrated in FIGS. 9 and 10, Comparative Example 1 fails to cover a portion of the DCI-P3 color gamut.

However, unlike Comparative Example 1, the display apparatus 1 according to one or more embodiments includes the sloped area 231S. In one or more embodiments, the wavelength of light perceived by the user may vary depending on the user's field of view. For example, as the user's field of view increases, the wavelength of light perceived by the user may decrease. As the user's field of view increases, the wavelength of light perceived by the user may shift toward a shorter wavelength. Even if (e.g., when) the user views the display apparatus 1 from the front of the display apparatus 1, the user's viewing angle with respect to the sloped area 231S of the display apparatus 1 according to one or more embodiments may be greater than 0°. For this reason, the wavelength of light perceived by the user may be shortened for light emitted from the third display element DPE3 including the sloped area 231S. Therefore, the display apparatus 1 according to one or more embodiments may cover all (e.g., substantially all) areas of the DCI-P3 color gamut. For example, the display apparatus 1 having an excellent or suitable color gamut may be provided.

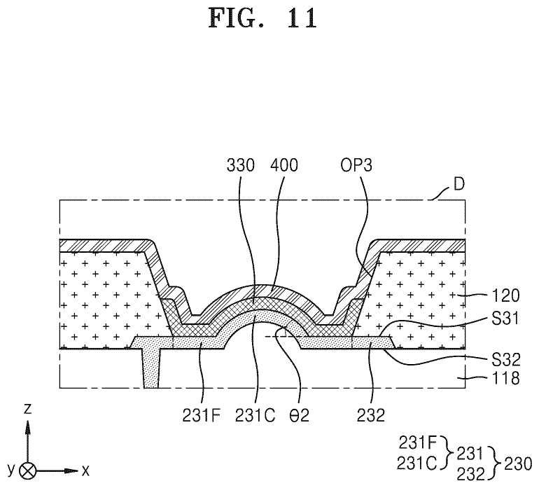

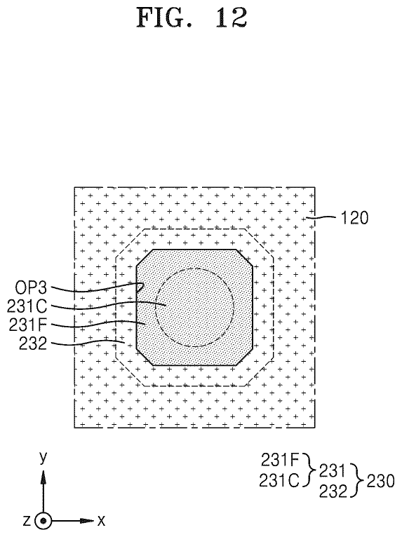

FIG. 11 is a cross-sectional view schematically illustrating a portion of the display apparatus 1 according to one or more embodiments. For example, FIG. 11 is a cross-sectional view schematically illustrating a third display element DPE3 of the display apparatus 1 according to one or more embodiments. FIG. 12 is a plan view schematically illustrating a portion of the display apparatus 1 according to one or more embodiments. FIG. 12 is a plan view on a pixel defining layer 120. However, for convenience of description, a third-2 electrode area 232 below the pixel defining layer 120 is illustrated together. For example, FIG. 11 corresponds to FIG. 7, and FIG. 12 corresponds to FIG. 8.

Because the display apparatus 1 according to one or more embodiments is substantially similar to the display apparatus 1 as described in one or more embodiments with reference to FIGS. 1-8, differences from the display apparatus 1 as described in one or more embodiments with reference to FIGS. 1-8 are mainly or predominantly described. In FIGS. 11 and 12, because the same reference numerals as those in FIGS. 1-8 denote substantially the same members, redundant descriptions thereof may not be provided.

The display apparatus 1 as described in one or more embodiments with reference to FIGS. 1-8 may include the third pixel electrode 230 including the third-1 electrode area 231 and the third-2 electrode area 232, and the third-1 electrode area 231 may include the flattened area 231F. The display apparatus 1 according to one or more embodiments may also include the third pixel electrode 230 including the third-1 electrode area 231 and the third-2 electrode area 232, and the third-1 electrode area 231 may include the flattened area 231F.

However, as illustrated in FIG. 11, the third-1 electrode area 231 of the display apparatus 1 according to one or more embodiments may further include a convex area 231C. The convex area 231C may be an area that further protrudes in the opposite direction of the substrate 100 or toward the substrate 100 than the flattened area 231F. In one or more embodiments, a third-1 electrode surface S31 of at least a portion of the convex area 231C may be inclined with respect to the first substrate surface SS1 of the substrate 100. For example, an angle between the third-1 electrode surface S31 of the convex area 231C adjacent to the flattened area 231F and the first substrate surface SS1 of the substrate 100 may be a second angle θ2, and the second angle θ2 may be about 10° to about 80°.

For example, the distance between the third-1 electrode surface S31 of the convex area 231C and the first substrate surface SS1 may be different from the distance between the third-1 electrode surface S31 of the flattened area 231F and the first substrate surface SS1. For example, the distance between the third-1 electrode surface S31 of the convex area 231C and the first substrate surface SS1 may be greater than the distance between the third-1 electrode surface S31 of the flattened area 231F and the first substrate surface SS1. In one or more embodiments, the distance between the third-1 electrode surface S31 of the convex area 231C and the first substrate surface SS1 may be less than the distance between the third-1 electrode surface S31 of the flattened area 231F and the first substrate surface SS1.

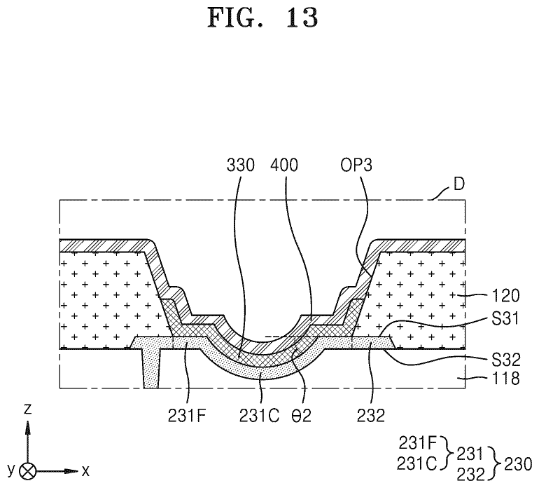

Although FIG. 11 illustrates that the convex area 231C further protrudes in the opposite direction of the substrate 100 than the flattened area 231F, embodiments the present disclosure are not limited thereto. As illustrated in FIG. 13, which is a cross-sectional view schematically illustrating a portion of the display apparatus 1 according to one or more embodiments, the convex area 231C may further protrude in the direction of the substrate 100 than the flattened area 231F. In one or more embodiments, the third-1 electrode surface S31 of at least a portion of the convex area 231C may be inclined with respect to the first substrate surface SS1 of the substrate 100. For example, an angle between the third-1 electrode surface S31 of the convex area 231C adjacent to the flattened area 231F and the first substrate surface SS1 of the substrate 100 may be a second angle θ2, and the second angle θ2 may be about 10° to about 80°.

As illustrated in FIG. 12, the flattened area 231F may surround the convex area 231C. For example, the convex area 231C may be surrounded by the flattened area 231F, and the flattened area 231F may be surrounded by the third-2 electrode area 232. For example, in a plan view, the flattened area 231F may surround the convex area 231C. In one or more embodiments, the flattened area 231F may be adjacent to the inner surface of the pixel defining layer 120 that is to define the third opening OP3. However, embodiments of the present disclosure are not limited thereto.

In one or more embodiments, even if (e.g., when) the user views the display apparatus 1 from the front of the display apparatus 1, the user's viewing angle with respect to the convex area 231C of the display apparatus 1 according to one or more embodiments may be greater than 0°. For this reason, the wavelength of light perceived by the user may be shortened for light emitted from the third display element DPE3 including the convex area 231C. Therefore, the display apparatus 1 according to one or more embodiments may cover all (e.g., substantially all) areas of the DCI-P3 color gamut. For example, the display apparatus 1 having an excellent or suitable color gamut may be provided. Although FIGS. 11 and 12 illustrate that the third pixel electrode 230 includes only the convex area 231C and not include the sloped area 231S, embodiments of the present disclosure are not limited thereto.

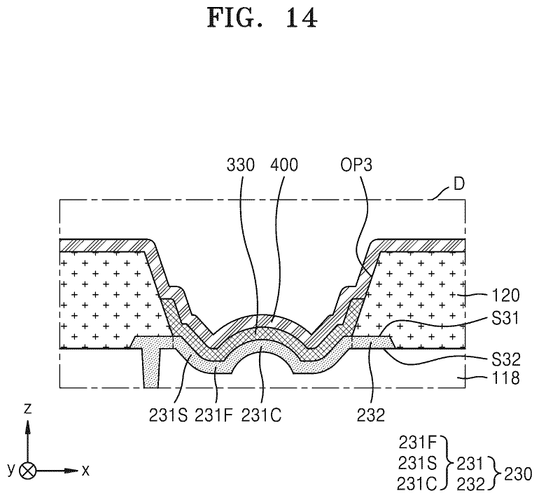

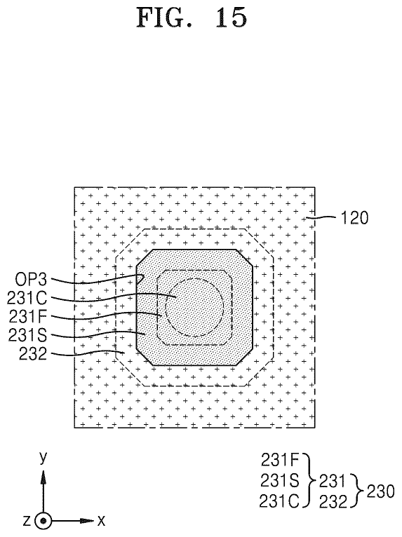

FIG. 14 is a plan view schematically illustrating a portion of the display apparatus 1 according to one or more embodiments. For example, FIG. 14 is a cross-sectional view schematically illustrating a third display element DPE3 of the display apparatus 1 according to one or more embodiments. FIG. 15 is a plan view schematically illustrating a portion of the display apparatus 1 according to one or more embodiments. FIG. 15 is a plan view on a pixel defining layer 120. However, for convenience of description, a third-2 electrode area 232 below the pixel defining layer 120 is illustrated together. For example, FIG. 14 corresponds to FIG. 7, and FIG. 15 corresponds to FIG. 8.

Because the display apparatus 1 according to one or more embodiments is substantially similar to the display apparatus 1 as described in one or more embodiments with reference to FIGS. 1-8 and the display apparatus 1 as described in one or more embodiments with reference to FIGS. 11 and 12, the following description is given to focus on differences from the display apparatus 1 as described in one or more embodiments with reference to FIGS. 1-8 and the display apparatus 1 as described in one or more embodiments with reference to FIGS. 11 and 12. In FIGS. 14 and 15, because the same reference numerals as those in FIGS. 1-8, 11, and 12 denote substantially the same members, redundant descriptions thereof may not be provided.

The display apparatus 1 as described in one or more embodiments with reference to FIGS. 1-8 and the display apparatus 1 as described in one or more embodiments with reference to FIGS. 11 and 12 may include the third pixel electrode 230 including the third-1 electrode area 231 and the third-2 electrode area 232, and the third-1 electrode area 231 may include the flattened area 231F. The display apparatus 1 according to one or more embodiments may also include the third pixel electrode 230 including the third-1 electrode area 231 and the third-2 electrode area 232, and the third-1 electrode area 231 may include the flattened area 231F.

However, as illustrated in FIG. 14, the third-1 electrode area 231 of the display apparatus 1 according to one or more embodiments may further include a sloped area 231S and a convex area 231C. The sloped area 231S may be an area where the third-1 electrode surface S31 of the sloped area 231S is inclined with respect to the first substrate surface SS1 of the substrate 100. The convex area 231C may be an area that further protrudes in the opposite direction of the substrate 100 or toward the substrate 100 than the flattened area 231F. In one or more embodiments, a third-1 electrode surface S31 of at least a portion of the convex area 231C may be inclined with respect to the first substrate surface SS1 of the substrate 100.

As illustrated in FIG. 15, the flattened area 231F may surround the convex area 231C, and the sloped area 231S may surround the flattened area 231F. In one or more embodiments, the sloped area 231S may be adjacent to the inner surface of the pixel defining layer 120 that is to define the third opening OP3. For example, the convex area 231C may be surrounded by the flattened area 231F, the flattened area 231F may be surrounded by the sloped area 231S, and the sloped area 231S may be surrounded by the third-2 electrode area 232. For example, in a plan view, the flattened area 231F may surround the convex area 231C, and the sloped area 231S may surround the flattened area 231F.

In one or more embodiments, even if (e.g., when) the user views the display apparatus 1 from the front of the display apparatus 1, the user's viewing angle with respect to the sloped area 231S and the convex area 231C of the display apparatus 1 according to one or more embodiments may be greater than 0°. For this reason, the wavelength of light perceived by the user may be shortened for light emitted from the third display element DPE3 including the sloped area 231S and the convex area 231C. Therefore, the display apparatus 1 according to one or more embodiments may cover all (e.g., substantially all) areas of the DCI-P3 color gamut. For example, the display apparatus 1 having an excellent or suitable color gamut may be provided.

In one or more embodiments, FIG. 4 and/or the like illustrates that one display element includes only one emission layer, but embodiments of the present disclosure are not limited thereto. For example, one display element may include a plurality of emission layers.

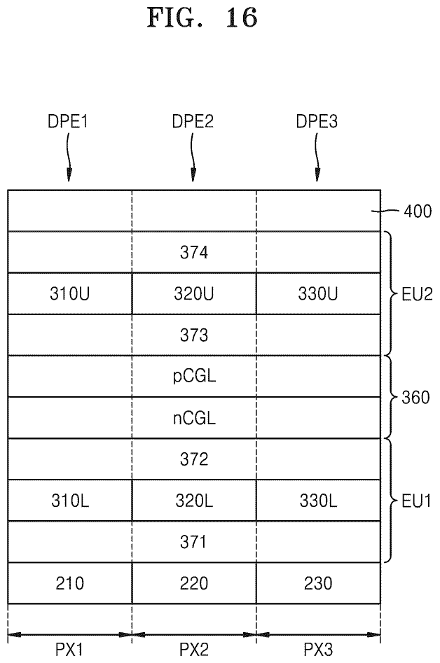

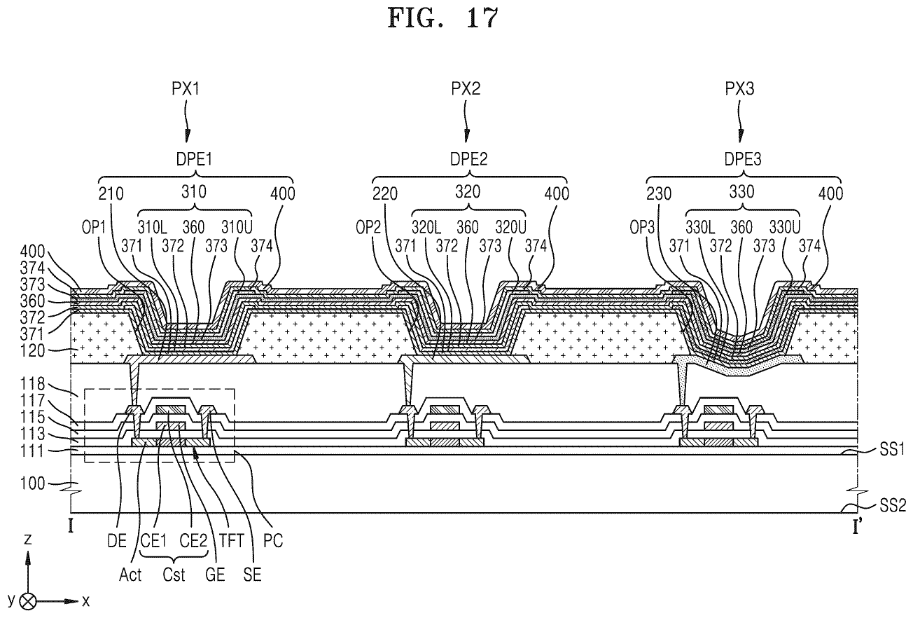

FIG. 16 is a conceptual diagram schematically illustrating a portion of a display apparatus according to one or more embodiments. For example, FIG. 16 is a conceptual diagram schematically illustrating a stacked structure of display elements in each of the plurality of pixels PX of the display apparatus 1 according to one or more embodiments. FIG. 17 is a cross-sectional view schematically illustrating the display apparatus 1 according to one or more embodiments. FIG. 17 corresponds to FIG. 4.

As illustrated in FIGS. 16 and 17, each of a first display element DPE1, a second display element DPE2, and a third display element DPE3 may be provided in a tandem structure including a plurality of emission layers. Because each of a first display element DPE1, a second display element DPE2, and a third display element DPE3 has a structure in which a plurality of emission layers are stacked, color purity and light emission efficiency may be improved or enhanced.

In one or more embodiments, each of a first emission layer 310, a second emission layer 320, and a third emission layer 330 included in the display element may include a plurality of sub-emission layers. For example, the first emission layer 310 may include a first lower emission layer 310L and a first upper emission layer 310U. The first lower emission layer 310L may be on the first pixel electrode 210, and the first upper emission layer 310U may be on the first lower emission layer 310L so as to overlap the first lower emission layer 310L. In one or more embodiments, the second emission layer 320 may include a second lower emission layer 320L and a second upper emission layer 320U. The second lower emission layer 320L may be on the second pixel electrode 220, and the second upper emission layer 320U may be on the second lower emission layer 320L so as to overlap the second lower emission layer 320L. In one or more embodiments, the third emission layer 330 may include a third lower emission layer 330L and a third upper emission layer 330U. The third lower emission layer 330L may be on the third pixel electrode 230, and the third upper emission layer 330U may be on the third lower emission layer 330L so as to overlap the third lower emission layer 330L.

The first lower emission layer 310L, the second lower emission layer 320L, and the third lower emission layer 330L may be individually patterned and provided for the first display element DPE1, the second display element DPE2, and the third display element DPE3, respectively. In one or more embodiments, the first upper emission layer 310U, the second upper emission layer 320U, and the third upper emission layer 330U may be individually patterned and provided for the first display element DPE1, the second display element DPE2, and the third display element DPE3, respectively.

The first display element DPE1 may be to emit red light, the second display element DPE2 may be to emit green light, and the third display element DPE3 may be to emit blue light. To implement such light emission, the first lower emission layer 310L and the first upper emission layer 310U may be to emit red light, the second lower emission layer 320L and the second upper emission layer 320U may be to emit green light, and the third lower emission layer 330L and the third upper emission layer 330U may be to emit blue light. The first lower emission layer 310L, the second lower emission layer 320L, and the third lower emission layer 330L may constitute a first emission unit EU1, and the first upper emission layer 310U, the second upper emission layer 320U, and the third upper emission layer 330U may constitute a second emission unit EU2.

In one or more embodiments, a charge generation layer (CGL) 360 may be between the first lower emission layer 310L and the first upper emission layer 310U, between the second lower emission layer 320L and the second upper emission layer 320U, and between the third lower emission layer 330L and the third upper emission layer 330U. The CGL 360 may be provided to be generally available across the first display element DPE1, the second display element DPE2, and/or the third display element DPE3. The CGL 360 may serve to supply charges to the first emission unit EU1 including the first lower emission layer 310L, the second lower emission layer 320L, and the third lower emission layer 330L, and the second emission unit EU2 including the first upper emission layer 310U, the second upper emission layer 320U, and the third upper emission layer 330U. In one or more embodiments, the light emission efficiency of each of the first display element DPE1, the second display element DPE2, and the third display element DPE3 each having a structure in which the emission layers are stacked may be further improved or enhanced.

The CGL 360 may include a negative-type (n-type) CGL nCGL to supply electrons to the first emission unit EU1 and a positive-type (p-type) CGL pCGL to supply holes to the second emission unit EU2.

The n-type CGL nCGL may include a negative-type (n-type) dopant material and an n-type host material. The n-type dopant material may be metals of Groups 1 and 2 in the periodic table of the elements, an organic material capable of injecting electrons, or any mixture thereof. For example, the n-type dopant material may be one selected from among an alkali metal and an alkaline earth metal. For example, the n-type CGL nCGL may include an inorganic layer doped with an alkali metal, such as lithium (Li), sodium (Na), potassium (K), and/or cesium (Cs), and/or an alkaline earth metal, such as magnesium (Mg), strontium (Sr), barium (Ba), and/or radium (Ra), but embodiments of the present disclosure are not limited thereto. The n-type host material may include one selected from among the materials capable of transferring electrons, for example, tris(8-hydroxyquinolino)aluminum (Alq₃), 8-hydroxyquinolinolato-lithium (Liq), 2-(4-biphenylyl)-5-(4-tert-butylphenyl)-1,3,4oxadiazole (PBD), 3-(4-biphenyl) 4-phenyl-5-tert-butylphenyl-1,2,4-triazole (TAZ), spiro-PBD, bis(2-methyl-8-quinolinolate)-4-(phenylphenolato)aluminium (BAlq), aluminum (III) bis(2-methyl-8-quinolinolato)triphenylsilanolate (SAlq), 2,2′,2-(1,3,5-benzinetriyl)-tris(1-phenyl-1-H-benzimidazole (TPBi), oxadiazole, triazole, phenanthroline, benzoxazole, and benzthiazole, and embodiments of the present disclosure are not limited thereto.

The p-type CGL pCGL may include a positive-type (p-type) dopant material and a p-type host material. The p-type dopant material may include a metal oxide, an organic material, such as tetrafluoro-tetracyanoquinodimethane (F4-TCNQ), hexaazatriphenylene-hexacarbonitrile (HAT-CN), and/or hexaazatriphenylene, and/or a metal material, such as V₂O₅, MoOₓ, and/or WO₃, but embodiments of the present disclosure are not limited thereto. The p-type host material may include a material including at least one selected from among materials capable of transporting holes, for example, N,N-dinaphthyl-N,N′-diphenyl benzidine (NPD), N,N′-bis(naphthalene-1-yl)-N,N′-bis(phenyl)-2,2′-dimethylbenzidine, N,N′-bis-(3-methylphenyl)-N,N′-bis-(phenyl)-benzidine (TPD), and 4,4′,4-tris(N-3-methylphenyl-N-phenyl-amino)-triphenylamine (MTDATA), but embodiments of the present disclosure are not limited thereto.

In one or more embodiments, the first emission unit EU1 may include a first lower emission layer 310L, a second lower emission layer 320L, and a third lower emission layer 330L, and may further include a first common layer 371 and a second common layer 372. For example, the first common layer 371 may be between the first pixel electrode 210 and the first lower emission layer 310L, between the second pixel electrode 220 and the second lower emission layer 320L, and between the third pixel electrode 230 and the third lower emission layer 330L. The second common layer 372 may be between the first lower emission layer 310L and the CGL 360, between the second lower emission layer 320L and the CGL 360, and between the third lower emission layer 330L and the CGL 360. Each of the first common layer 371 and the second common layer 372 may be integrally provided across the first display element DPE1, the second display element DPE2, and/or the third display element DPE3.

For example, the first emission unit EU1 of the first pixel PX1 may include the first common layer 371, the first lower emission layer 310L, and the second common layer 372, which are sequentially stacked on the first pixel electrode 210. The first emission unit EU1 of the second pixel PX2 may include the first common layer 371, the second lower emission layer 320L, and the second common layer 372, which are sequentially stacked on the second pixel electrode 220. The first emission unit EU1 of the third pixel PX3 may include the first common layer 371, the third lower emission layer 330L, and the second common layer 372, which are sequentially stacked on the third pixel electrode 230. Each of the first common layer 371 and the second common layer 372 may be a common layer formed or provided continuously (e.g., substantially continuously) in the first pixel PX1, the second pixel PX2, and the third pixel PX3.

The first common layer 371 may be a single layer or two or more layers. For example, if (e.g., when) the first common layer 371 includes a high molecular weight material, the first common layer 371 may be a single-layered hole transport layer (HTL) and may include polyethylene dihydroxythiophene (PEDOT: poly-(3,4)-ethylene-dihydroxy thiophene) and/or polyaniline (PANI). If (e.g., when) the first common layer 371 includes a low molecular weight material, the first common layer 371 may include a hole injection layer (HIL) and/or an HTL. The second common layer 372 may not be always included and may be optional. The second common layer 372 may be a single layer or two or more layers. The second common layer 372 may include an electron transport layer (ETL) and/or an electron injection layer (EIL).

In one or more embodiments, the second emission unit EU2 may include a first upper emission layer 310U, a second upper emission layer 320U, and a third upper emission layer 330U, and may further include a third common layer 373 and a fourth common layer 374. For example, the third common layer 373 may be between the CGL 360 and the first upper emission layer 310U, between the CGL 360 and the second upper emission layer 320U, and between the CGL 360 and the third upper emission layer 330U. The fourth common layer 374 may be between the first upper emission layer 310U and the opposite electrode 400, between the second upper emission layer 320U and the opposite electrode 400, and between the third upper emission layer 330U and the opposite electrode 400. Each of the third common layer 373 and the fourth common layer 374 may be integrally provided across the first display element DPE1, the second display element DPE2, and/or the third display element DPE3.

For example, the second emission unit EU2 of the first pixel PX1 may include the third common layer 373, the first upper emission layer 310U, and the fourth common layer 374, which are sequentially stacked on the CGL 360. The second emission unit EU2 of the second pixel PX2 may include the third common layer 373, the second upper emission layer 320U, and the fourth common layer 374, which are sequentially stacked on the CGL layer 360. The second emission unit EU2 of the third pixel PX3 may include the third common layer 373, the third upper emission layer 330U, and the fourth common layer 374, which are sequentially stacked on the CGL 360. Each of the third common layer 373 and the fourth common layer 374 may be a common layer formed or provided continuously (e.g., substantially continuously) in the first pixel PX1, the second pixel PX2, and the third pixel PX3.

The third common layer 373 may be a single layer or two or more layers. For example, if (e.g., when) the third common layer 373 includes a high molecular weight material, the third common layer 373 may be a single-layered HTL and may include PEDOT or PANI. If (e.g., when) the third common layer 373 includes a low molecular weight material, the third common layer 373 may include an HIL and an HTL. The fourth common layer 374 may not be always included and may be optional. The fourth common layer 374 may be a single layer or two or more layers. The fourth common layer 374 may include an ETL and/or an EIL.

In one or more embodiments, the thickness of the first lower emission layer 310L and the first upper emission layer 310U, the thickness of the second lower emission layer 320L and the second upper emission layer, and the thickness of the third lower emission layer 330L and the third upper emission layer 330U may be determined according to the resonance distance. Because an auxiliary layer is a layer added to suitably adjust the resonance distance, the auxiliary layer may include a resonance auxiliary material. For example, the auxiliary layer may include substantially the same material as the HTL. The auxiliary layer may be provided on at least one selected from among the first display element DPE1, the second display element DPE2, or the third display element DPE3 so as to match the resonance distances of each of the first pixel PX1, the second pixel PX2, and the third pixel PX3. For example, the first display element DPE1 may include an auxiliary layer below the first upper emission layer 310U.

In one or more embodiments, the first display element DPE1, the second display element DPE2, and the third display element DPE3 may further include a capping layer outside the opposite electrode 400. The capping layer may improve or enhance light emission efficiency by the principle of constructive interference. In one or more embodiments, the light extraction efficiency of the first display element DPE1, the second display element DPE2, and the third display element DPE3 may increase or enhance, so that the light emission efficiency of the first display element DPE1, the second display element DPE2, and the third display element DPE3 may be improved or enhanced.

According to one or more embodiments, a display apparatus having an excellent or suitable color gamut may be implemented or provided. The scope of the present disclosure is not limited by such an effect.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure have been described with reference to the figures, it will be understood by those of ordinary skill in the art that one or more suitable changes in form and more details may be made therein without departing from the spirit and scope as defined by the following claims and equivalents thereof.

What is claimed is:

1. A display apparatus, comprising:
a substrate comprising a first substrate surface and a second substrate surface opposite to the first substrate surface;
an organic insulating layer on the first substrate surface;
a first pixel electrode, a second pixel electrode, and a third pixel electrode apart from each other on the organic insulating layer;
a first emission layer on the first pixel electrode, wherein the first emission layer is to emit red light;
a second emission layer on the second pixel electrode, wherein the second emission layer is to emit green light;
a third emission layer on the third pixel electrode, wherein the third emission layer is to emit blue light; and
a pixel defining layer to define a first opening to expose a central portion of the first pixel electrode, a second opening to expose a central portion of the second pixel electrode, and a third opening to expose a central portion of the third pixel electrode,
wherein the third emission layer comprises a dopant material comprising a phosphorescent dopant, a thermally activated delayed fluorescent dopant, or any combination thereof,
a wavelength indicated by a peak having a maximum intensity in a photoluminescence (PL) spectrum of light emitted by the dopant material is about 460 nm to about 490 nm, and
the third pixel electrode comprises a third-1 electrode area and a third-2 electrode area, wherein the third-1 electrode area is to overlap the third opening and comprises a sloped area and a flattened area, and the third-2 electrode area is to overlap the pixel defining layer.

2. The display apparatus as claimed in claim 1, wherein the third pixel electrode comprises a third-1 electrode surface in a direction opposite to the substrate and a third-2 electrode surface in a direction of the substrate,
the third-1 electrode surface of the sloped area is inclined with respect to the first substrate surface, and
the third-1 electrode surface of the flattened area is parallel to the first substrate surface.

3. The display apparatus as claimed in claim 2, wherein an angle between the third-1 electrode surface of the sloped area and the first substrate surface is about 10° to about 80°.

4. The display apparatus as claimed in claim 1, wherein, in a plan view, the sloped area surrounds the flattened area.

5. The display apparatus as claimed in claim 4, wherein the sloped area is adjacent to an inner surface of the pixel defining layer that is to define the third opening.

6. The display apparatus as claimed in claim 1, wherein the first pixel electrode comprises a first-1 electrode surface in a direction opposite to the substrate and a first-2 electrode surface in a direction of the substrate,
the second pixel electrode comprises a second-1 electrode surface in a direction opposite to the substrate and a second-2 electrode surface in a direction of the substrate,
the first-1 electrode surface of the first pixel electrode is parallel to the first substrate surface, and
the second-1 electrode surface of the second pixel electrode is parallel to the first substrate surface.

7. The display apparatus as claimed in claim 1, further comprising an opposite electrode across the first pixel electrode, the second pixel electrode, and the third pixel electrode.

8. The display apparatus as claimed in claim 1, wherein the phosphorescent dopant comprises an organometallic compound represented by Formula 401: 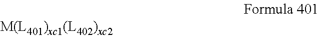
wherein, in Formula 401, M is a transition metal,
L₄₀₁ is a ligand represented by Formula 402, xc1 is 1, 2, or 3, and when xc1 is 2 or 3, two or more L₄₀₁(s) are identical to or different from each other, and
L₄₀₂ is an organic ligand, xc2 is 0, 1, 2, 3, or 4, and when xc2 is 2, 3, or 4, two or more L₄₀₂(s) are identical to or different from each other, 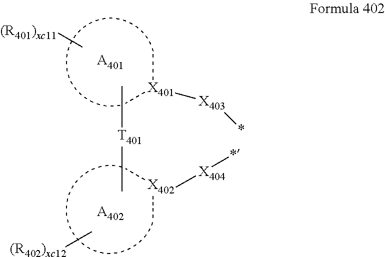
wherein, in Formula 402,
X₄₀₁ and X₄₀₂ are each independently nitrogen or carbon,
a ring A₄₀₁ and a ring A₄₀₂ are each independently a C₃-C₆₀ carbocyclic group or a C₁-C₆₀ heterocyclic group,
T₄₀₁ is a single bond, *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)═*′, or *═C═*′,
X₄₀₃ and X₄₀₄ are each independently a chemical bond, O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ are each independently hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
xc11 and xc12 are each independently an integer of 0 to 10,
* and *′ each indicate a binding site to M in Formula 401, and
R₁₀ₐ is selected from among:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —Ge(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl C₆₀ heterocyclic group, a C₆-C₆₀ aryloxy group, a C₆-C₆₀ arylthio group, —Si(Q₂₁)(Q₂₂)(Q₂₃), —Ge(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —Ge(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁₁ to Q₁₃, Q₂₁ to Q₂₃, Q₃₁ to Q₃₃, Q₄₀₁ to Q₄₀₃, and Q₄₁₁ to Q₄₁₄ are each independently hydrogen; deuterium; —F; —Cl; —Br; —I; a hydroxyl group; a cyano group; a nitro group; a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, a cyano group, a phenyl group, a biphenyl group, or any combination thereof; or a C₃-C₆₀ carbocyclic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or any combination thereof.

9. The display apparatus as claimed in claim 1, wherein a difference between a triplet energy level (eV) of the thermally activated delayed fluorescent dopant and a singlet energy level (eV) of the thermally activated delayed fluorescent dopant is about 0 eV to about 0.5 eV.

10. The display apparatus as claimed in claim 1, wherein the thermally activated delayed fluorescent dopant comprises a material comprising at least one electron donor and at least one electron acceptor, a material comprising a C₈-C₆₀ polycyclic group comprising two or more cyclic groups condensed while sharing boron (B), or any combination thereof.

11. A display apparatus, comprising:
a substrate comprising a first substrate surface and a second substrate surface opposite to the first substrate surface;
an organic insulating layer on the first substrate surface;
a first pixel electrode, a second pixel electrode, and a third pixel electrode apart from each other on the organic insulating layer;
a first emission layer on the first pixel electrode, wherein the first emission layer is to emit red light;
a second emission layer on the second pixel electrode, wherein the second emission layer is to emit green light;
a third emission layer on the third pixel electrode, wherein the third emission layer is to emit blue light; and
a pixel defining layer to define a first opening to expose a central portion of the first pixel electrode, a second opening to expose a central portion of the second pixel electrode, and a third opening to expose a central portion of the third pixel electrode,
wherein the third emission layer comprises a dopant material comprising a phosphorescent dopant, a thermally activated delayed fluorescent dopant, or any combination thereof,
a wavelength indicated by a peak having a maximum intensity in a photoluminescence (PL) spectrum of light emitted by the dopant material is about 460 nm to about 490 nm, and
the third pixel electrode comprises a third-1 electrode area and a third-2 electrode area, wherein the third-1 electrode area is to overlap the third opening and comprises a flattened area and a convex area, and the third-2 electrode area is to overlap the pixel defining layer.

12. The display apparatus as claimed in claim 11, wherein the third pixel electrode comprises a third-1 electrode surface in a direction opposite to the substrate and a third-2 electrode surface in a direction of the substrate,
the third-1 electrode surface of at least a portion of the convex area is inclined with respect to the first substrate surface, and
the third-1 electrode surface of the flattened area is parallel to the first substrate surface.

13. The display apparatus as claimed in claim 12, wherein an angle between the third-1 electrode surface of the convex area adjacent to the flattened area and the first substrate surface is about 10° to about 80°.

14. The display apparatus as claimed in claim 11, wherein, in a plan view, the flattened area surrounds the convex area.

15. The display apparatus as claimed in claim 14, wherein the flattened area is adjacent to an inner surface of the pixel defining layer that is to define the third opening.

16. The display apparatus as claimed in claim 11, wherein the first pixel electrode comprises a first-1 electrode surface in a direction opposite to the substrate and a first-2 electrode surface in a direction of the substrate,
the second pixel electrode comprises a second-1 electrode surface in a direction opposite to the substrate and a second-2 electrode surface in a direction of the substrate,
the first-1 electrode surface of the first pixel electrode is parallel to the first substrate surface, and
the second-1 electrode surface of the second pixel electrode is parallel to the first substrate surface.

17. The display apparatus as claimed in claim 11, further comprising an opposite electrode across the first pixel electrode, the second pixel electrode, and the third pixel electrode.

18. The display apparatus as claimed in claim 11, wherein the phosphorescent dopant comprises an organometallic compound represented by Formula 401: 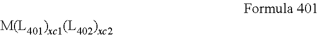
wherein, in Formula 401, M is a transition metal,
L₄₀₁ is a ligand represented by Formula 402, xc1 is 1, 2, or 3, and when xc1 is 2 or 3, two or more L₄₀₁(s) are identical to or different from each other, and
L₄₀₂ is an organic ligand, xc2 is 0, 1, 2, 3, or 4, and when xc2 is 2, 3, or 4, two or more L₄₀₂(s) are identical to or different from each other, 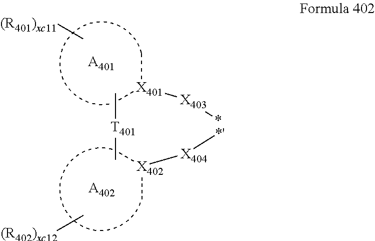
wherein, in Formula 402,
X₄₀₁ and X₄₀₂ are each independently nitrogen or carbon,
a ring A₄₀₁ and a ring A₄₀₂ are each independently a C₃-C₆₀ carbocyclic group or a C₁-C₆₀ heterocyclic group,
T₄₀₁ is a single bond, *—O—*′, *—S—*′, *—C(═O)—*′, *—N(Q₄₁₁)-*′, *—C(Q₄₁₁)(Q₄₁₂)-*′, *—C(Q₄₁₁) ═C(Q₄₁₂)-*′, *—C(Q₄₁₁)═*′, or *═C═*′,
X₄₀₃ and X₄₀₄ are each independently a chemical bond, O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ are each independently hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
xc11 and xc12 are each independently an integer of 0 to 10,
* and *′ each indicate a binding site to M in Formula 401, and
R₁₀ₐ is selected from among:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —Ge(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl C₆₀ heterocyclic group, a C₆-C₆₀ aryloxy group, a C₆-C₆₀ arylthio group, —Si(Q₂₁)(Q₂₂)(Q₂₃), —Ge(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —Ge(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁₁ to Q₁₃, Q₂₁ to Q₂₃, Q₃₁ to Q₃₃, Q₄₀₁ to Q₄₀₃, and Q₄₁₁ to Q₄₁₄ are each independently hydrogen; deuterium; —F; —Cl; —Br; —I; a hydroxyl group; a cyano group; a nitro group; a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, a cyano group, a phenyl group, a biphenyl group, or any combination thereof; or a C₃-C₆₀ carbocyclic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or any combination thereof.

19. The display apparatus as claimed in claim 11, wherein a difference between a triplet energy level (eV) of the thermally activated delayed fluorescent dopant and a singlet energy level (eV) of the thermally activated delayed fluorescent dopant is about 0 eV to about 0.5 eV.

20. The display apparatus as claimed in claim 11, wherein the thermally activated delayed fluorescent dopant comprises a material comprising at least one electron donor and at least one electron acceptor, a material comprising a C₈-C₆₀ polycyclic group comprising two or more cyclic groups condensed while sharing boron (B), or any combination thereof.
